(19) United States
(12) Patent Application Publication
(10) Pub. No.: US 2025/0194153 A1
(43) Pub. Date: Jun. 12, 2025

(54) BACKSIDE GATE CONTACT AND BACKSIDE CROSS-COUPLE CONNECT

(71) Applicant: International Business Machines Corporation, Armonk, NY (US)

(72) Inventors: Ruilong Xie, Niskayuna, NY (US); Chanro Park, Clifton Park, NY (US); Julien Frougier, Albany, NY (US); Juntao Li, Cohoes, NY (US); Min Gyu Sung, Latham, NY (US); Minhaz Abedin, Albany, NY (US)

(21) Appl. No.: 18/532,754

(22) Filed: Dec. 7, 2023

(51) Int. Cl. H01L 29/423; H01L 23/528; H01L 27/088; H01L 29/06; H01L 29/417; H01L 29/66; H01L 29/775; H01L 29/786

(52) U.S. Cl. CPC H10D 30/6735; H01L 23/5286; H10D 30/014; H10D 30/43; H10D 30/6757; H10D 62/121; H10D 64/017; H10D 64/258; H10D 84/83

(57) ABSTRACT

A semiconductor structure includes a backside gate extension extending from a frontside gate region through a dielectric isolation layer, a backside gate contact partially disposed on the backside gate extension, and a backside interconnect connected to the backside gate extension by the backside gate contact.

### BACKGROUND

Semiconductors and integrated circuit chips have become ubiquitous within many products, particularly as they continue to decrease in cost and size. There is a continued desire to reduce the size of structural features and/or to provide a greater number of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Illustrative embodiments of the present application include techniques for use in semiconductor manufacture. In an illustrative embodiment, a semiconductor structure comprises a backside gate extension extending from a frontside gate region through a dielectric isolation layer, a backside gate contact partially disposed on the backside gate extension, and a backside interconnect connected to the backside gate extension by the backside gate contact.

The semiconductor structure of the illustrative embodiment advantageously allows for a backside interconnect to have a power line and a signal line thereby reducing process complexity and improving routing congestion.

In one or more additional illustrative embodiments, as may be combined with the preceding paragraphs, the semiconductor structure further comprises a backside gate extension cap layer disposed on the backside gate extension.

In one or more additional illustrative embodiments, as may be combined with the preceding paragraphs, the backside gate contact is further partially disposed on the backside gate extension cap layer.

In one or more additional illustrative embodiments, as may be combined with the preceding paragraphs, the semiconductor structure further comprises a first frontside source/drain region and a second frontside source/drain region, a backside source/drain contact disposed on the first frontside source/drain region, and a first backside source/drain contact cap layer disposed on the backside source/drain contact.

In one or more additional illustrative embodiments, as may be combined with the preceding paragraphs, the semiconductor structure further comprises a backside sacrificial placeholder disposed on the second frontside source/drain region, and a second backside source/drain contact cap layer disposed on the backside sacrificial placeholder.

In one or more additional illustrative embodiments, as may be combined with the preceding paragraphs, the semiconductor structure further comprises a backside source/drain contact via connecting a backside source/drain contact to the backside interconnect.

In one or more additional illustrative embodiments, as may be combined with the preceding paragraphs, the semiconductor structure further comprises a backside source/drain contact cap layer disposed on the backside source/drain contact and the backside source/drain contact via:

In one or more additional illustrative embodiments, as may be combined with the preceding paragraphs, the frontside gate region is disposed within a nanosheet field-effect transistor.

In one or more additional illustrative embodiments, as may be combined with the preceding paragraphs, the semiconductor structure further comprises a frontside metal gate contact connecting the frontside gate region to a frontside back-end-of-the line interconnect.

In another illustrative embodiment, a semiconductor structure comprises a backside gate extension extending from a frontside gate region through a dielectric isolation layer, and a backside cross-couple connect connecting a backside source/drain contact to the backside gate extension.

The semiconductor structure of the illustrative embodiment advantageously allows for a backside interconnect to have a power line and a signal line thereby reducing process complexity and improving routing congestion.

In one or more additional illustrative embodiments, as may be combined with the preceding paragraphs, the backside cross-couple connect is partially disposed on the backside gate extension.

In one or more additional illustrative embodiments, as may be combined with the preceding paragraphs, the semiconductor structure further comprises a backside gate extension cap layer disposed on the backside gate extension.

In one or more additional illustrative embodiments, as may be combined with the preceding paragraphs, the backside cross-couple connect is further partially disposed on the backside gate extension cap layer.

In one or more additional illustrative embodiments, as may be combined with the preceding paragraphs, the semiconductor structure further comprises a first frontside source/drain region disposed on the backside source/drain contact, and a backside source/drain contact cap layer disposed on the backside source/drain contact and the backside cross-couple connect.

In one or more additional illustrative embodiments, as may be combined with the preceding paragraphs, the semiconductor structure further comprises a second frontside source/drain region adjacent the first frontside source/drain region, and a source/drain metal contact connecting the second frontside source/drain region to a back-end-of-the line interconnect.

In one or more additional illustrative embodiments, as may be combined with the preceding paragraphs, the frontside gate region is disposed within a nanosheet field-effect transistor.

In one or more additional illustrative embodiments, as may be combined with the preceding paragraphs, the semiconductor structure further comprises a frontside metal gate contact connecting the frontside gate region to a frontside back-end-of-the line interconnect.

In yet another illustrative embodiment, an integrated circuit comprises one or more semiconductor devices. At least one of the one or more semiconductor devices is a semiconductor device according to one or more of the foregoing illustrative embodiments.

The integrated circuit of the illustrative embodiment advantageously allows for a backside interconnect of the semiconductor structures to have a power line and a signal line thereby reducing process complexity and improving routing congestion.

These and other exemplary embodiments will be described in or become apparent from the following detailed description of exemplary embodiments, which is to be read in connection with the accompanying drawings.

### BRIEF DESCRIPTION OF THE DRAWINGS

Exemplary embodiments will be described below in more detail, with reference to the accompanying drawings, of which:

FIG. 1A is a top-down view of a semiconductor structure for use at the first-intermediate fabrication stage, according to an illustrative embodiment.

FIG. 1B is a cross-sectional view of the semiconductor structure taken along the X-X axis of FIG. 1A for use at the first-intermediate fabrication stage, according to an illustrative embodiment.

FIG. 1C is a cross-sectional view of the semiconductor structure taken along the Y1-Y1 axis of FIG. 1A for use at the first-intermediate fabrication stage, according to an illustrative embodiment.

FIG. 1D is a cross-sectional view of the semiconductor structure taken along the Y2-Y2 axis of FIG. 1A for use at the first-intermediate fabrication stage, according to an illustrative embodiment.

FIG. 2A is a cross-sectional view of the semiconductor structure taken along the X-X axis of FIG. 1A for use at a second-intermediate fabrication stage, according to an illustrative embodiment.

FIG. 2B is a cross-sectional view of the semiconductor structure taken along the Y1-Y1 axis of FIG. 1A for use at the second-intermediate fabrication stage, according to an illustrative embodiment.

FIG. 2C is a cross-sectional view of the semiconductor structure taken along the Y2-Y2 axis of FIG. 1A for use at the second-intermediate fabrication stage, according to an illustrative embodiment.

FIG. 3A is a cross-sectional view of the semiconductor structure taken along the X-X axis of FIG. 1A for use at a third-intermediate fabrication stage, according to an illustrative embodiment.

FIG. 3B is a cross-sectional view of the semiconductor structure taken along the Y1-Y1 axis of FIG. 1A for use at the third-intermediate fabrication stage, according to an illustrative embodiment.

FIG. 3C is a cross-sectional view of the semiconductor structure taken along the Y2-Y2 axis of FIG. 1A for use at the third-intermediate fabrication stage, according to an illustrative embodiment.

FIG. 4A is a cross-sectional view of the semiconductor structure taken along the X-X axis of FIG. 1A for use at a fourth-intermediate fabrication stage, according to an illustrative embodiment.

FIG. 4B is a cross-sectional view of the semiconductor structure taken along the Y1-Y1 axis of FIG. 1A for use at the fourth-intermediate fabrication stage, according to an illustrative embodiment.

FIG. 4C is a cross-sectional view of the semiconductor structure taken along the Y2-Y2 axis of FIG. 1A for use at the fourth-intermediate fabrication stage, according to an illustrative embodiment.

FIG. 5A is a cross-sectional view of the semiconductor structure taken along the X-X axis of FIG. 1A for use at a fifth-intermediate fabrication stage, according to an illustrative embodiment.

FIG. 5B is a cross-sectional view of the semiconductor structure taken along the Y1-Y1 axis of FIG. 1A for use at the fifth-intermediate fabrication stage, according to an illustrative embodiment.

FIG. 5C is a cross-sectional view of the semiconductor structure taken along the Y2-Y2 axis of FIG. 1A for use at the fifth-intermediate fabrication stage, according to an illustrative embodiment.

FIG. 6A is a cross-sectional view of the semiconductor structure taken along the X-X axis of FIG. 1A for use at a sixth-intermediate fabrication stage, according to an illustrative embodiment.

FIG. 6B is a cross-sectional view of the semiconductor structure taken along the Y1-Y1 axis of FIG. 1A for use at the sixth-intermediate fabrication stage, according to an illustrative embodiment.

FIG. 6C is a cross-sectional view of the semiconductor structure taken along the Y2-Y2 axis of FIG. 1A for use at the sixth-intermediate fabrication stage, according to an illustrative embodiment.

FIG. 7A is a cross-sectional view of the semiconductor structure taken along the X-X axis of FIG. 1A for use at a seventh-intermediate fabrication stage, according to an illustrative embodiment.

FIG. 7B is a cross-sectional view of the semiconductor structure taken along the Y1-Y1 axis of FIG. 1A for use at the seventh-intermediate fabrication stage, according to an illustrative embodiment.

FIG. 7C is a cross-sectional view of the semiconductor structure taken along the Y2-Y2 axis of FIG. 1A for use at the seventh-intermediate fabrication stage, according to an illustrative embodiment.

FIG. 8A is a cross-sectional view of the semiconductor structure taken along the X-X axis of FIG. 1A for use at an eighth-intermediate fabrication stage, according to an illustrative embodiment.

FIG. 8B is a cross-sectional view of the semiconductor structure taken along the Y1-Y1 axis of FIG. 1A for use at the eighth-intermediate fabrication stage, according to an illustrative embodiment.

FIG. 8C is a cross-sectional view of the semiconductor structure taken along the Y2-Y2 axis of FIG. 1A for use at the eighth-intermediate fabrication stage, according to an illustrative embodiment.

FIG. 9A is a cross-sectional view of the semiconductor structure taken along the X-X axis of FIG. 1A for use at a ninth-intermediate fabrication stage, according to an illustrative embodiment.

FIG. 9B is a cross-sectional view of the semiconductor structure taken along the Y1-Y1 axis of FIG. 1A for use at the ninth-intermediate fabrication stage, according to an illustrative embodiment.

FIG. 9C is a cross-sectional view of the semiconductor structure taken along the Y2-Y2 axis of FIG. 1A for use at the ninth-intermediate fabrication stage, according to an illustrative embodiment.

FIG. 10A is a cross-sectional view of the semiconductor structure taken along the X-X axis of FIG. 1A for use at a tenth-intermediate fabrication stage, according to an illustrative embodiment.

FIG. 10B is a cross-sectional view of the semiconductor structure taken along the Y1-Y1 axis of FIG. 1A for use at the tenth-intermediate fabrication stage, according to an illustrative embodiment.

FIG. 10C is a cross-sectional view of the semiconductor structure taken along the Y2-Y2 axis of FIG. 1A for use at the tenth-intermediate fabrication stage, according to an illustrative embodiment.

FIG. 11A is a cross-sectional view of the semiconductor structure taken along the X-X axis of FIG. 1A for use at an eleventh-intermediate fabrication stage, according to an illustrative embodiment.

FIG. 11B is a cross-sectional view of the semiconductor structure taken along the Y1-Y1 axis of FIG. 1A for use at the eleventh-intermediate fabrication stage, according to an illustrative embodiment.

FIG. 11C is a cross-sectional view of the semiconductor structure taken along the Y2-Y2 axis of FIG. 1A for use at the eleventh-intermediate fabrication stage, according to an illustrative embodiment.

FIG. 12A is a cross-sectional view of the semiconductor structure taken along the X-X axis of FIG. 1A for use at a twelfth-intermediate fabrication stage, according to an illustrative embodiment.

FIG. 12B is a cross-sectional view of the semiconductor structure taken along the Y1-Y1 axis of FIG. 1A for use at the twelfth-intermediate fabrication stage, according to an illustrative embodiment.

FIG. 12C is a cross-sectional view of the semiconductor structure taken along the Y2-Y2 axis of FIG. 1A for use at the twelfth-intermediate fabrication stage, according to an illustrative embodiment.

FIG. 13A is a cross-sectional view of the semiconductor structure taken along the X-X axis of FIG. 1A for use at a thirteenth-intermediate fabrication stage, according to an illustrative embodiment.

FIG. 13B is a cross-sectional view of the semiconductor structure taken along the Y1-Y1 axis of FIG. 1A for use at the thirteenth-intermediate fabrication stage, according to an illustrative embodiment.

FIG. 13C is a cross-sectional view of the semiconductor structure taken along the Y2-Y2 axis of FIG. 1A for use at the thirteenth-intermediate fabrication stage, according to an illustrative embodiment.

FIG. 14A is a cross-sectional view of the semiconductor structure taken along the X-X axis of FIG. 1A for use at a fourteenth-intermediate fabrication stage, according to an illustrative embodiment.

FIG. 14B is a cross-sectional view of the semiconductor structure taken along the Y1-Y1 axis of FIG. 1A for use at the fourteenth-intermediate fabrication stage, according to an illustrative embodiment.

FIG. 14C is a cross-sectional view of the semiconductor structure taken along the Y2-Y2 axis of FIG. 1A for use at the fourteenth-intermediate fabrication stage, according to an illustrative embodiment.

FIG. 15A is a cross-sectional view of the semiconductor structure taken along the X-X axis of FIG. 1A for use at a fifteenth-intermediate fabrication stage, according to an illustrative embodiment.

FIG. 15B is a cross-sectional view of the semiconductor structure taken along the Y1-Y1 axis of FIG. 1A for use at the fifteenth-intermediate fabrication stage, according to an illustrative embodiment.

FIG. 15C is a cross-sectional view of the semiconductor structure taken along the Y2-Y2 axis of FIG. 1A for use at the fifteenth-intermediate fabrication stage, according to an illustrative embodiment.

FIG. 15D is a cross-sectional view of the semiconductor structure taken along the X′-X′ axis of FIG. 1A for use at the fifteenth-intermediate fabrication stage, according to an illustrative embodiment.

FIG. 16A is a cross-sectional view of the semiconductor structure taken along the X-X axis of FIG. 1A for use at a sixteenth-intermediate fabrication stage, according to an illustrative embodiment.

FIG. 16B is a cross-sectional view of the semiconductor structure taken along the Y1-Y1 axis of FIG. 1A for use at the sixteenth-intermediate fabrication stage, according to an illustrative embodiment.

FIG. 16C is a cross-sectional view of the semiconductor structure taken along the Y2-Y2 axis of FIG. 1A for use at the sixteenth-intermediate fabrication stage, according to an illustrative embodiment.

FIG. 16D is a cross-sectional view of the semiconductor structure taken along the X′-X′ axis of FIG. 1A for use at the sixteenth-intermediate fabrication stage, according to an illustrative embodiment.

FIG. 17A is a cross-sectional view of the semiconductor structure taken along the X-X axis of FIG. 1A for use at a seventeenth-intermediate fabrication stage, according to an illustrative embodiment.

FIG. 17B is a cross-sectional view of the semiconductor structure taken along the Y1-Y1 axis of FIG. 1A for use at the seventeenth-intermediate fabrication stage, according to an illustrative embodiment.

FIG. 17C is a cross-sectional view of the semiconductor structure taken along the Y2-Y2 axis of FIG. 1A for use at the seventeenth-intermediate fabrication stage, according to an illustrative embodiment.

FIG. 17D is a cross-sectional view of the semiconductor structure taken along the X′-X′ axis of FIG. 1A for use at the seventeenth-intermediate fabrication stage, according to an illustrative embodiment.

FIG. 17E and is a top-down view of the semiconductor structure for use at the seventeenth-intermediate fabrication stage, according to an illustrative embodiment.

FIG. 18A is a cross-sectional view of the semiconductor structure taken along the X-X axis of FIG. 1A for use at the eighteenth-intermediate fabrication stage, according to an illustrative embodiment.

FIG. 18B is a cross-sectional view of the semiconductor structure taken along the Y1-Y1 axis of FIG. 1A for use at the eighteenth-intermediate fabrication stage, according to an illustrative embodiment.

FIG. 18C is a cross-sectional view of the semiconductor structure taken along the Y2-Y2 axis of FIG. 1A for use at the eighteenth-intermediate fabrication stage, according to an illustrative embodiment.

FIG. 18D is a cross-sectional view of the semiconductor structure taken along the X′-X′ axis of FIG. 1A for use at the eighteenth-intermediate fabrication stage, according to an illustrative embodiment.

FIG. 19A is a cross-sectional view of the semiconductor structure taken along the X-X axis of FIG. 1A starting from FIG. 12A for use at a first-intermediate fabrication stage, according to an alternative illustrative embodiment.

FIG. 19B is a cross-sectional view of the semiconductor structure taken along the Y1-Y1 axis of FIG. 1A for use at the first-intermediate fabrication stage, according to an alternative illustrative embodiment.

FIG. 19C is a cross-sectional view of the semiconductor structure taken along the Y2-Y2 axis of FIG. 1A for use at the first-intermediate fabrication stage, according to an alternative illustrative embodiment.

FIG. 20A is a cross-sectional view of the semiconductor structure taken along the X-X axis of FIG. 1A for use at a second-intermediate fabrication stage, according to an alternative illustrative embodiment.

FIG. 20B is a cross-sectional view of the semiconductor structure taken along the Y1-Y1 axis of FIG. 1A for use at the second-intermediate fabrication stage, according to an illustrative embodiment.

FIG. 20C is a cross-sectional view of the semiconductor structure taken along the Y2-Y2 axis of FIG. 1A for use at the second-intermediate fabrication stage, according to an alternative illustrative embodiment.

FIG. 21A is a cross-sectional view of the semiconductor structure taken along the X-X axis of FIG. 1A for use at a third-intermediate fabrication stage, according to an alternative illustrative embodiment.

FIG. 21B is a cross-sectional view of the semiconductor structure taken along the Y1-Y1 axis of FIG. 1A for use at the third-intermediate fabrication stage, according to an alternative illustrative embodiment.

FIG. 21C is a cross-sectional view of the semiconductor structure taken along the Y2-Y2 axis of FIG. 1A for use at the third-intermediate fabrication stage, according to an alternative illustrative embodiment.

FIG. 21D is a top-down view of the semiconductor structure for use at the third-intermediate fabrication stage, according to an alternative illustrative embodiment.

FIG. 22A is a cross-sectional view of the semiconductor structure taken along the X-X axis of FIG. 1A for use at a fourth-intermediate fabrication stage, according to an alternative illustrative embodiment.

FIG. 22B is a cross-sectional view of the semiconductor structure taken along the Y1-Y1 axis of FIG. 1A for use at the fourth-intermediate fabrication stage, according to an alternative illustrative embodiment.

FIG. 22C is a cross-sectional view of the semiconductor structure taken along the Y2-Y2 axis of FIG. 1A for use at the fourth-intermediate fabrication stage, according to an alternative illustrative embodiment.

### DETAILED DESCRIPTION

This disclosure relates generally to semiconductor devices, and more particularly to semiconductor structures having a backside gate contact and backside cross-couple connect, and methods for their fabrication. However, it is to be understood that embodiments of the present disclosure are not limited to the illustrative methods, apparatus, systems and devices but instead are more broadly applicable to other suitable methods, apparatus, systems and devices.

Detailed embodiments of the semiconductor structures and methods are disclosed herein. The method steps described below do not form a complete process flow for manufacturing integrated circuits, such as, semiconductor devices. The present embodiments can be practiced in conjunction with the integrated circuit fabrication techniques currently used in the art and only so much of the commonly practiced process steps are included as are necessary for an understanding of the described embodiments. The figures represent cross-section portions of a semiconductor structure after fabrication and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element.

As used herein, “lateral,” “lateral side,” “lateral surface” refers to a side surface of an element (e.g., a layer, opening, etc.), such as a left or right-side surface in the drawings.

As used herein, “width” or “length” refers to a size of an element (e.g., a layer, trench, hole, opening, etc.) in the drawings measured from a side surface to an opposite surface of the element.

As used herein, terms such as “upper”, “lower”, “right”, “left”, “vertical”, “horizontal”, “top”, “bottom”, and derivatives thereof are to be broadly construed to relate to the disclosed structures and methods, as oriented in the drawings, wherein such structures may be understood to have the same configuration (e.g., layers stacked in the same order) even if the structure is rotated to a different angle from that shown in the drawings.

As used herein, unless otherwise specified, terms such as “on”, “overlying”, “atop”, “on top”, “positioned on” or “positioned atop” mean that a first element is present on a second element, wherein intervening elements may be present between the first element and the second element. As used herein, unless otherwise specified, the term “directly” used in connection with the terms “on”, “overlying”, “atop”, “on top”, “positioned on” or “positioned atop” or the term “direct contact” mean that a first element and a second element are connected without any intervening elements, such as, for example, intermediary conducting, insulating or semiconductor layers, present between the first element and the second element.

It is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description. It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment. The term “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present concept.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

In the interest of not obscuring the presentation of the embodiments of the present disclosure, in the following detailed description, some of the processing steps, materials, or operations that are known in the art may have been combined together for presentation and for illustration purposes and in some instances may not have been described in detail. Additionally, for brevity and maintaining a focus on distinctive features of elements of the present disclosure, description of previously discussed materials, processes, and structures may not be repeated with regard to subsequent Figures. In other instances, some processing steps or operations that are known may not be described. It should be understood that the following description is rather focused on the distinctive features or elements of the various embodiments of the present invention.

It is to be understood that the various layers, structures, and/or regions shown in the accompanying drawings are schematic illustrations that are not necessarily drawn to scale. In addition, for ease of explanation, one or more layers, structures, and regions of a type commonly used to form semiconductor devices or structures may not be explicitly shown in a given drawing. This does not imply that any layers, structures, and regions not explicitly shown are omitted from the actual semiconductor structures.

In general, the various processes used to form a semiconductor chip fall into four general categories, namely, film deposition, removal/etching, semiconductor doping, and patterning/lithography. Deposition is any process that grows, coats, or otherwise transfers a material onto the wafer. Available technologies include but are not limited to physical vapor deposition (“PVD”), chemical vapor deposition (“CVD”), electrochemical deposition (“ECD”), molecular beam epitaxy (“MBE”) and more recently, atomic layer deposition (“ALD”) among others. Another deposition technology is plasma enhanced chemical vapor deposition (“PECVD”), which is a process that uses the energy within the plasma to induce reactions at the wafer surface that would otherwise require higher temperatures associated with conventional CVD. Energetic ion bombardment during PECVD deposition can also improve the film's electrical and mechanical properties.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. The patterns created by lithography or photolithography typically are used to define or protect selected surfaces and portions of the semiconductor structure during subsequent etch processes.

Removal is any process such as etching or chemical-mechanical planarization (“CMP”) that removes material from the wafer. Examples of etch processes include either wet (e.g., chemical) or dry etch processes. One example of a removal process or dry etch process is ion beam etching (“IBE”). In general, IBE (or milling) refers to a dry plasma etch method that utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry etch process is reactive ion etching (“RIE”). In general, RIE uses chemically reactive plasma to remove material deposited on wafers. High-energy ions from the RIE plasma attack the wafer surface and react with the surface material(s) to remove the surface material(s).

In the IC chip fabrication industry, there are three sections referred to in a typical IC chip build: front-end-of-line (FEOL), back-end-of-line (BEOL), and the section that connects those two together, the middle-of-line (MOL). The FEOL is made up of the semiconductor devices, e.g., transistors, the BEOL is made up of interconnects and wiring, and the MOL is an interconnect between the FEOL and BEOL that includes material to prevent the diffusion of BEOL metals to FEOL devices. Accordingly, illustrative embodiments described herein may be directed to BEOL semiconductor processing and structures. BEOL is the second portion of IC fabrication where the individual devices (e.g., transistors, capacitors, resistors, etc.) become interconnected with wiring on the wafer, e.g., the metallization layer or layers. BEOL includes contacts, insulating layers (dielectrics), metal levels, and bonding sites for chip-to-package connections. In the BEOL, part of the fabrication stage contacts (pads), interconnect wires, vias and dielectric structures are formed. For modern IC processes, more than 10 metal layers may be added in the BEOL.

Embodiments described below may be applicable to FEOL processing and structures, BEOL processing and structures, or both FEOL and BEOL processing and structures. In particular, although an exemplary processing scheme may be illustrated using a FEOL processing scenario, such approaches may also be applicable to BEOL processing. Likewise, although an exemplary processing scheme may be illustrated using a BEOL processing scenario, such approaches may also be applicable to FEOL processing.

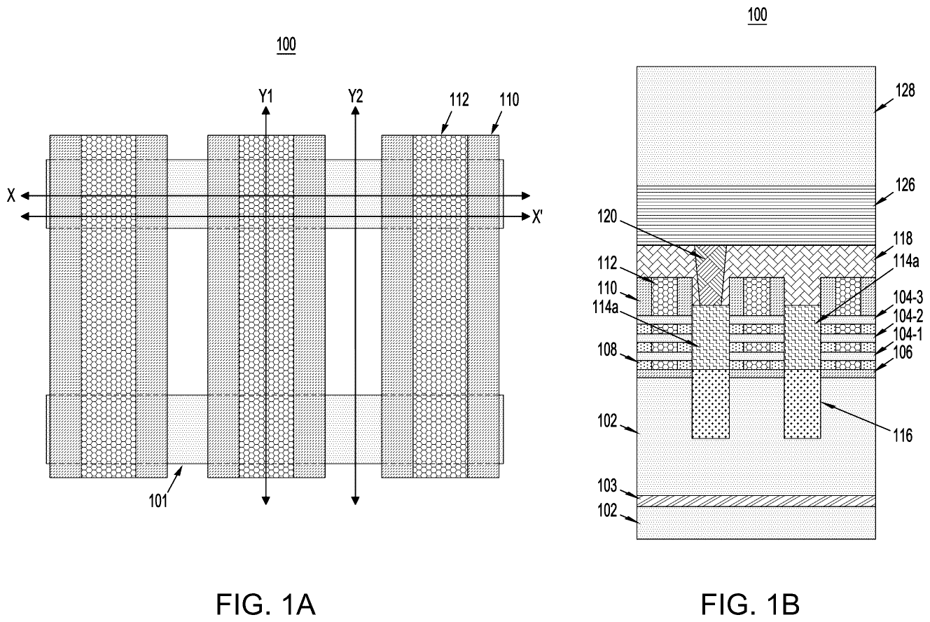

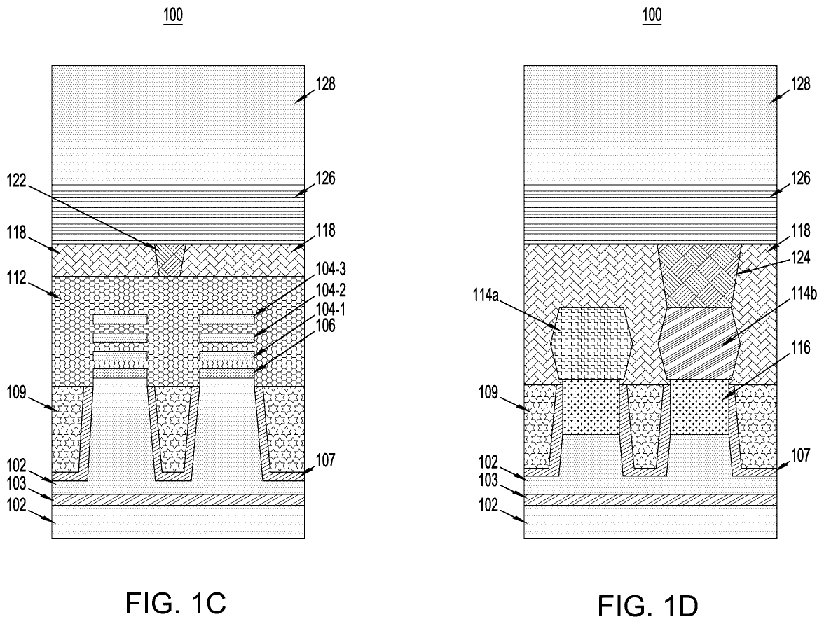

Referring now to the drawings in which like numerals represent the same or similar elements, FIGS. 1A-22C illustrate various processes for fabricating semiconductor structures with a backside gate contact and backside cross-couple connect. Note that the same reference numeral (100) is used to denote the semiconductor structure through the various intermediate fabrication stages illustrated in FIGS. 1A-22C. Note also that the semiconductor structures described herein can also be considered to be a semiconductor device and/or an integrated circuit, or some part thereof. For the purpose of clarity, some fabrication steps leading up to the production of the semiconductor structures as illustrated in FIGS. 1A-22C are omitted. In other words, one or more well-known processing steps which are not illustrated but are well-known to those of ordinary skill in the art have not been included in the figures. This is not intended to be interpreted as a limitation of any particular embodiment, or illustration, or scope of the claims.

Conventional backside interconnects have only a backside power line. However, it is desirable in present backside interconnects to have both a backside power line and a backside signal having a backside gate contact over the active region. Illustrative embodiments provide methods and structures for enabling a power and signal line at both the frontside and the backside of the stacked FETs. Referring now to FIG. 1A-18D, FIG. 1A is a top-down view of a semiconductor structure 100 with active regions 101 along with gate spacers 110 and a gate stack layer 112. FIG. 1B is a cross-sectional view of the semiconductor structure taken along the X-X axis of FIG. 1A, according to an illustrative embodiment. FIG. 1C is a cross-sectional view of the semiconductor structure taken along the Y1-Y1 axis of FIG. 1A, according to an illustrative embodiment. FIG. 1D is a cross-sectional view of the semiconductor structure taken along the Y2-Y2 axis of FIG. 1A, according to an illustrative embodiment.

Semiconductor structure 100 shows a substrate 102. Substrate 102 may be formed of any suitable semiconductor structure, including various silicon-containing materials including but not limited to silicon (Si), silicon germanium (SiGe), silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), zinc selenide (ZnSe), etc. In one illustrative embodiment, substrate 102 is silicon.

An etch stop layer 103 is formed in substrate 102. Etch stop layer 103 may comprise a buried oxide (BOX) layer or silicon germanium (SiGe), or another suitable material such as a III-V semiconductor epitaxial layer.

Nanosheets are initially formed over substrate 102, where the nanosheets include sacrificial layers (not shown), and nanosheet channel layers 104-1, 104-2 and 104-3 (collectively, nanosheet channel layers 104). The sacrificial layers are illustratively formed of different sacrificial materials, such that they may be etched or otherwise removed selective to one another. In some embodiments, the sacrificial layers are formed of SiGe, but with different percentages of Ge. For example, certain ones of the sacrificial layers may have a relatively higher percentage of Ge (e.g., 55% Ge), and other ones of the sacrificial layers may have a relatively lower percentage of Ge (e.g., 25% Ge). Other combinations of different sacrificial materials may be used in other embodiments. Nanosheet channel layers 104 may be formed of Si or another suitable material (e.g., a material similar to that used for substrate 102).

The nanosheets are then patterned for formation of STI regions 109 and FET stacks containing nanosheet channel layers 104. STI regions 109 may be formed of a dielectric material such as silicon dioxide (SiO₂), silicon oxycarbide (SiOC), silicon oxynitride (SiON), etc. STI regions 109 further include a liner layer 107 composed of, for example, SiN. Each of the FET stacks containing nanosheet channel layers 104 include a first FET device and a second FET device. However, this is merely illustrative and it is contemplated that any number of FET devices can be formed. The FET devices may comprise one of an nFET device or a pFET device and other ones of the FET devices may comprise one of a pFET device and an nFET device.

Semiconductor structure 100 further includes a self-aligned-silicon-isolation (SASI) layer 106, inner spacers 108, gate spacers 110, a gate stack layer 112, source/drain regions 114a and 114b, sacrificial placeholder layers 116 and an interlayer dielectric layer (ILD) layer 118.

SASI layer 106 may be formed of any suitable insulator, such as SiN, silicon boron carbide nitride (SiBCN), silicon oxycarbonitride (SiOCN), etc. SASI layer 106 is formed in the region previously occupied by a sacrificial layer, and may have similar sizing as the sacrificial layers.

Inner spacers 108 may be formed to fill indent spaces (e.g., resulting from indent etches of the sacrificial layers prior to their removal). Inner spacers 108 may be formed of silicon nitride (SiN) or another suitable material such as SiBCN, silicon carbide oxide (SiCO), SiOCN, etc.

Gate spacers 110 may be formed of materials similar to that of SASI layer 106. Gate spacers 110 may have widths (in direction X-X) that are similar to the widths of the inner spacers 108.

Gate stack layer 112 may comprise a gate dielectric layer and a gate conductor layer. The gate dielectric layer may be formed of a high-k dielectric material. Examples of high-k dielectric materials include but are not limited to metal oxides such as HfO₂, hafnium silicon oxide (Hf—Si—O), hafnium silicon oxynitride (HfSiON), lanthanum oxide (La₂O₃), lanthanum aluminum oxide (LaAlO₃), zirconium oxide (ZrO₂), zirconium silicon oxide, zirconium silicon oxynitride, tantalum oxide (Ta₂O₅), titanium oxide (TiO₂), barium strontium titanium oxide, barium titanium oxide, strontium titanium oxide, yttrium oxide (Y₂O₃), aluminum oxide (Al₂O₃), lead scandium tantalum oxide, and lead zinc niobate. The high-k dielectric material may further include dopants such as lanthanum (La), aluminum (Al), and magnesium (Mg). The gate dielectric layer may have a uniform thickness in the range of 1 nm to 3 nm.

The gate conductor layer may include a metal gate or work function metal (WFM). The WFM for the gate conductor layer may be titanium (Ti), titanium nitride (TiN), tantalum (Ta), tantalum nitride (TaN), aluminum (Al), titanium aluminum (TiAl), titanium aluminum carbon (TiAlC), a combination of Ti and Al alloys, a stack which includes a barrier layer (e.g., of TiN, TaN, etc.) followed by one or more of the aforementioned WFM materials, etc. It should be appreciated that various other materials may be used for the gate conductor layer as desired.

Source/drain regions 114a and 114b may be formed using epitaxial growth processes. Source/drain regions 114a and 114b may be suitably doped, such as using ion implantation, gas phase doping, plasma doping, plasma immersion ion implantation, cluster doping, infusion doping, liquid phase doping, solid phase doping, etc. N-type dopants may be selected from a group of phosphorus (P), arsenic (As) and antimony (Sb), and p-type dopants may be selected from a group of boron (B), boron fluoride (BF₂), gallium (Ga), indium (In), and thallium (Tl). In some embodiments, the epitaxy process comprises in-situ doping (dopants are incorporated in epitaxy material during epitaxy).

Epitaxial materials may be grown from gaseous or liquid precursors. Epitaxial materials may be grown using vapor-phase epitaxy (VPE), molecular-beam epitaxy (MBE), liquid-phase epitaxy (LPE), rapid thermal chemical vapor deposition (RTCVD), metal organic chemical vapor deposition (MOCVD), ultra-high vacuum chemical vapor deposition (UHVCVD), low-pressure chemical vapor deposition (LPCVD), limited reaction processing CVD (LRPCVD), or other suitable processes. Epitaxial silicon, silicon germanium (SiGe), germanium (Ge), and/or carbon doped silicon (Si:C) silicon can be doped during deposition (in-situ doped) by adding dopants, such as n-type dopants (e.g., phosphorus or arsenic) or p-type dopants (e.g., boron or gallium), depending on the type of transistor to be formed. The dopant concentration in the source/drain can range from 1×10¹⁹ cm-3 to 3×10²¹ cm⁻³, or preferably between 2×10²⁰ cm⁻³ to 3×10²¹ cm⁻³. In some embodiments, source/drain region 114a is a p-type source/drain region and source/drain region 114b is a n-type source/drain region.

Sacrificial placeholder layers 116 are formed in substrate 102 and coplanar with SASI layer 106. Sacrificial placeholder layers 116 are comprised of a sacrificial material or materials, such as SiGe, titanium oxide (TiOₓ), aluminum oxide (AlOₓ), silicon carbide (SiC), etc.

ILD layer 118 is formed over gate stack layer 112 and source/drain regions 114a and 114b. ILD layer 118 may be formed of any suitable isolating material, such as SiO₂, SiOC, SiON, etc.

Semiconductor structure 100 further includes frontside source/drain contacts 120 and 124 and a gate contact 122. Suitable metals for frontside source/drain contacts 120 and 124 and gate contact 122 include any conductive material such as, for example, a silicide liner such as Ti, Ni, NiPt, a metal adhesion layer TiN, TaN, and a conductive metal such as tungsten (W), aluminum (Al), copper (Cu), cobalt (Co), ruthenium (Ru), molybdenum (Mo), or any other suitable conductive material. In various embodiments, the conductive metal can be deposited by ALD, CVD, PVD, and/or plating.

Semiconductor structure 100 further includes a frontside BEOL interconnect 126 having various BEOL interconnect structures and a carrier wafer 128. For example, frontside BEOL interconnect 126 is a metallization structure that includes one or more metal layers disposed on a side of semiconductor structure 100 opposite of the side on which the backside BEOL metallization structure is disposed. The metal layers of the frontside BEOL interconnect 126 each have metal lines for making interconnections to the semiconductor device. In particular, frontside BEOL interconnect 126 includes one or more metal layers that include metal lines for carrying power signals (e.g., a positive and/or negative voltage signal and/or ground signal) for providing power routing between the backside and the frontside of the semiconductor structure 100. Power routing involves metal lines configured to carry a power signal. For example, the semiconductor structure 100 may require power to operate. In the example of FETs as semiconductor structure 100, a power signal may need to be coupled to a gate, source, and/or drain of the FET for its desired function and operation.

Carrier wafer 128 may be formed of materials similar to that of substrate 102, and may be formed over frontside BEOL interconnect 126 using a wafer bonding process, such as dielectric-to-dielectric bonding.

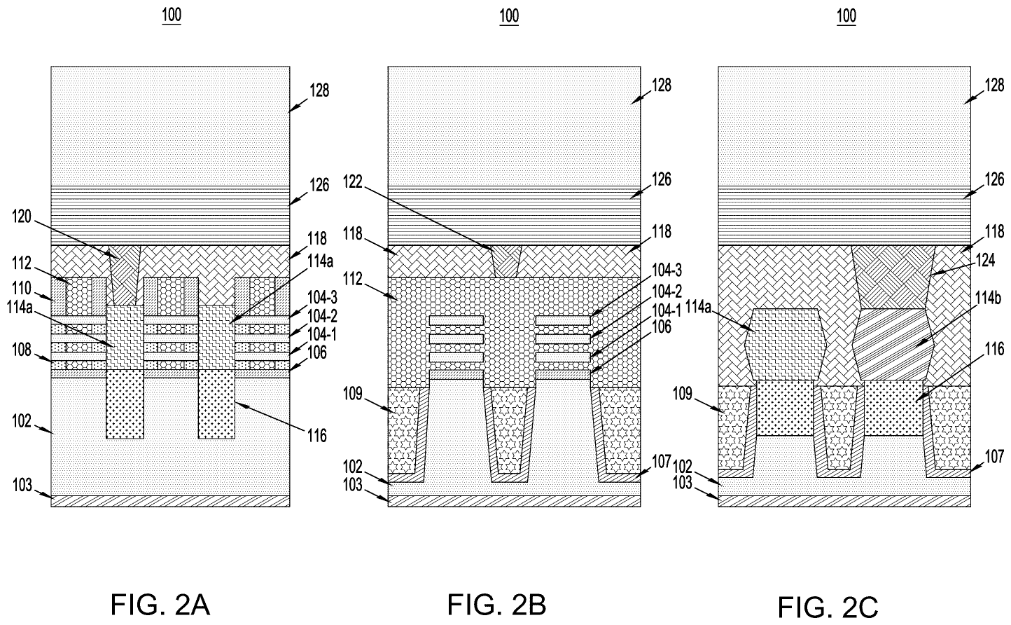

FIGS. 2A-2C illustrate semiconductor structure 100 at a second-intermediate fabrication stage. During this stage, the backside of substrate 102 is processed by, for example, flipping carrier wafer 128 over so that the backside of substrate 102 (i.e., the back surface) is facing up for backside processing. In particular, using the flipped structure, portions of substrate 102 may be removed from the backside using, for example, a substrate grinding, a planarization (e.g., using CMP) and a wet etch to selectively remove substrate 102 until etch stop layer 103 is reached.

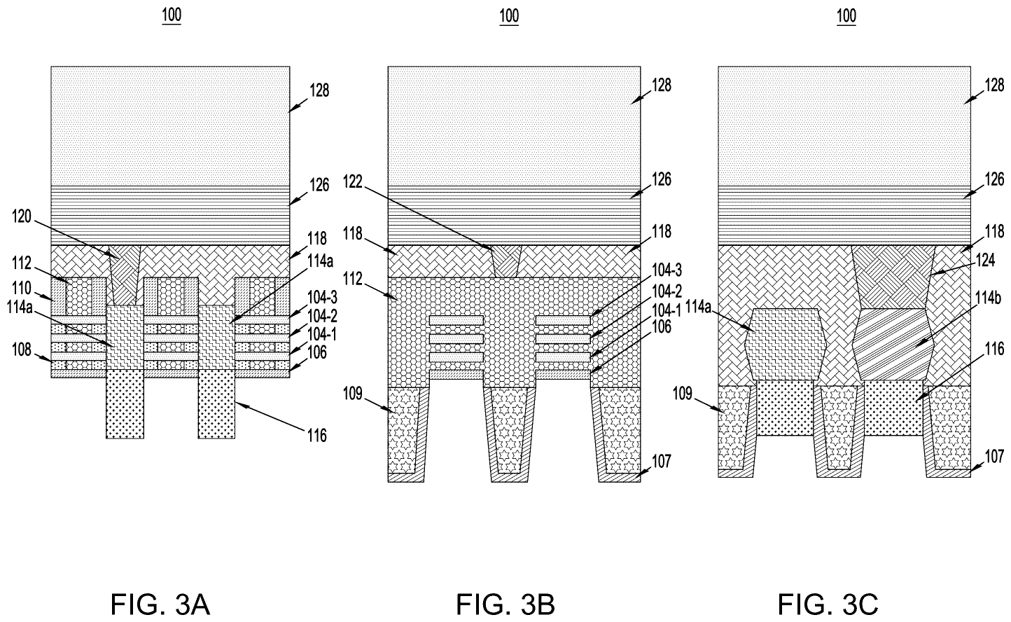

FIGS. 3A-3C illustrate semiconductor structure 100 at a third-intermediate fabrication stage. During this stage, etch stop layer 103 is selectively removed using, for example, a wet etch to selectively remove etch stop layer 103 until substrate 102 is reached. Next, the remaining portions of substrate 102 are removed to expose SASI layer 106, liner layer 107 and sacrificial placeholder layers 116. The remaining portions of substrate 102 can be removed utilizing a selective etch process such as a wet etch.

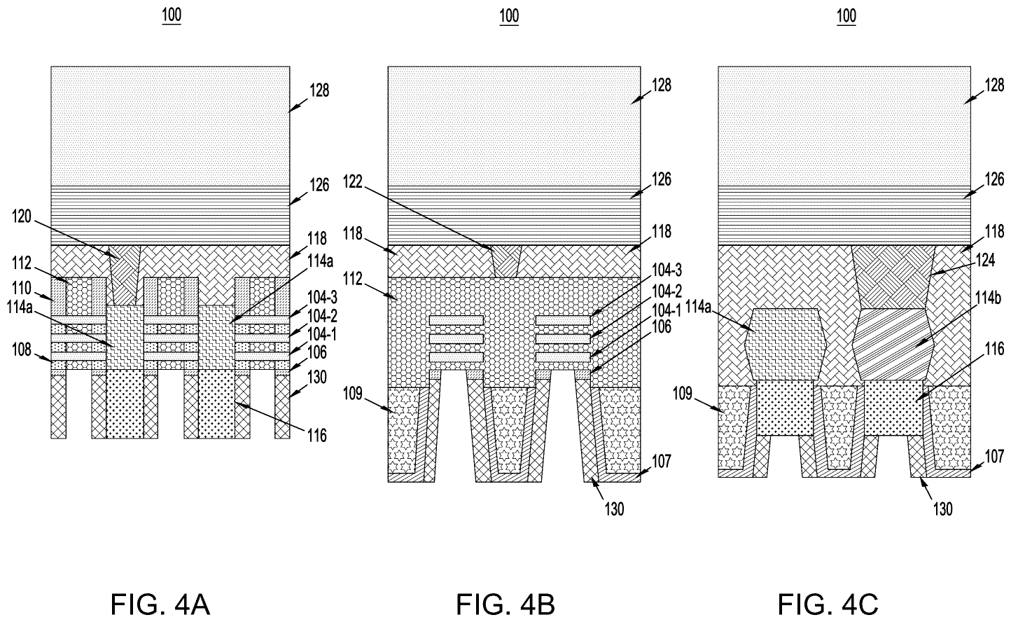

FIGS. 4A-4C illustrate semiconductor structure 100 at a fourth-intermediate fabrication stage. During this stage, a conformal spacer layer 130 is deposited on liner layer 107 and sacrificial placeholder layers 116 using any conventional deposition technique such as ALD, CVD, PVD, etc., following by an RIE process to etch through SASI layer 106 to expose gate stack layer 112. Suitable conformal material for conformal spacer layer 130 includes, for example, a nitride containing material such as SiN, SiBCN, SiOCN, etc.

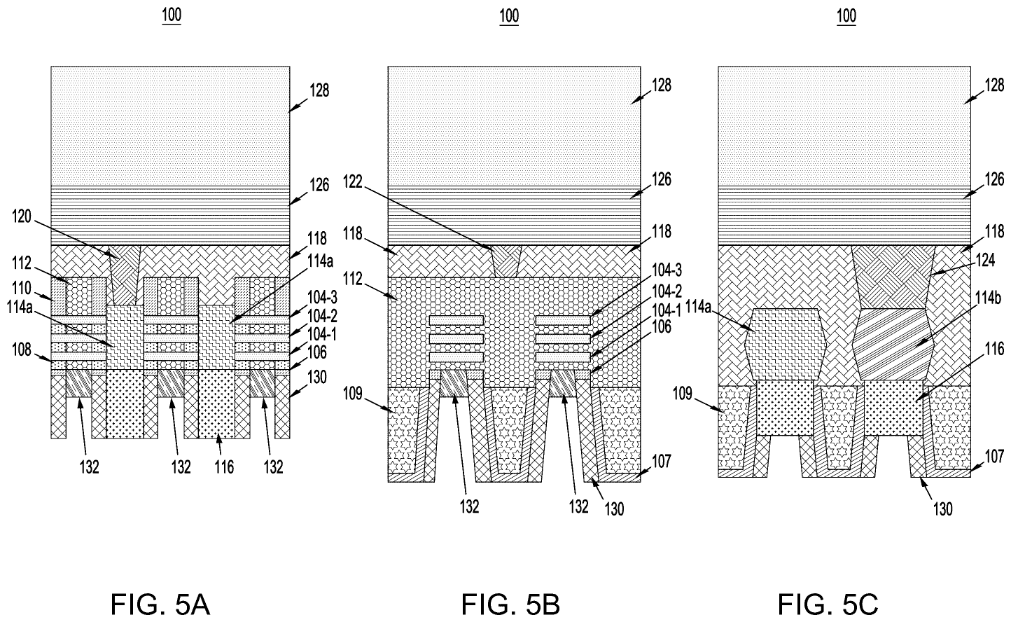

FIGS. 5A-5C illustrate semiconductor structure 100 at a fifth-intermediate fabrication stage. During this stage, a backside gate extension 132 is formed by either performing a selective metal growth process from the exposed gate metal or depositing a conductive metal on gate stack layer 112 first, after that a planarization process such as CMP is carried out to planarize any metal overfill, followed by an RIE process to recess the conductive metal to form backside gate extension 132. The conductive metal can be deposited in a similar manner and of a similar material as discussed above.

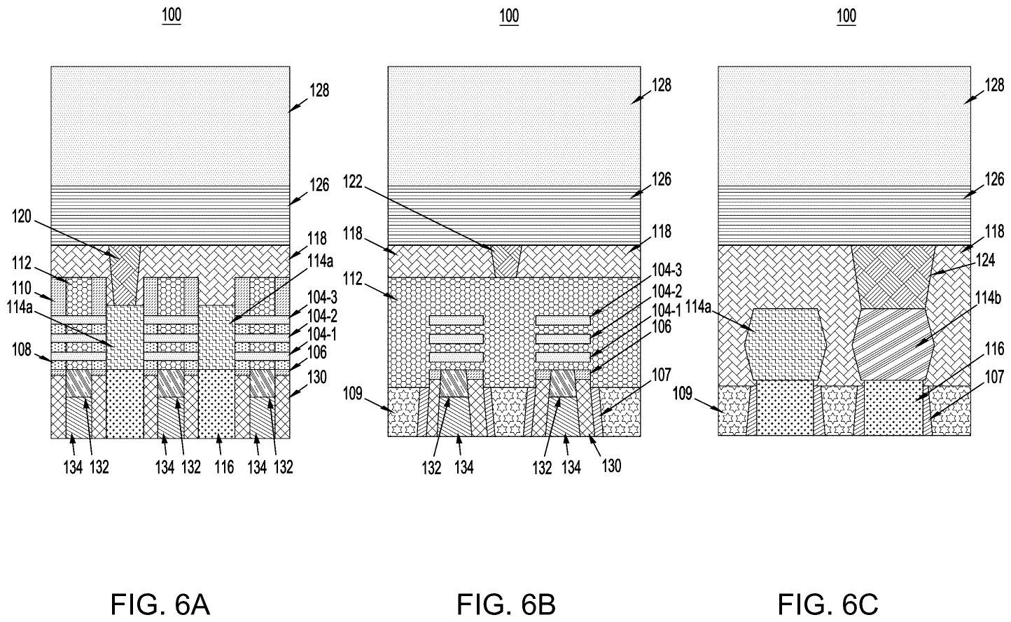

FIGS. 6A-6C illustrate semiconductor structure 100 at a sixth-intermediate fabrication stage. During this stage, a backside gate extension cap layer 134 is deposited on backside gate extension 132 and between opposing sidewalls of conformal spacer layer 130 using any convention deposition technique such as ALD, CVD, PVD, etc. Suitable material for backside gate extension cap layer 134 includes, for example, a nitride containing material such as SiN, SiBCN, SiOCN, etc. A planarization process such as CMP can be carried out if necessary.

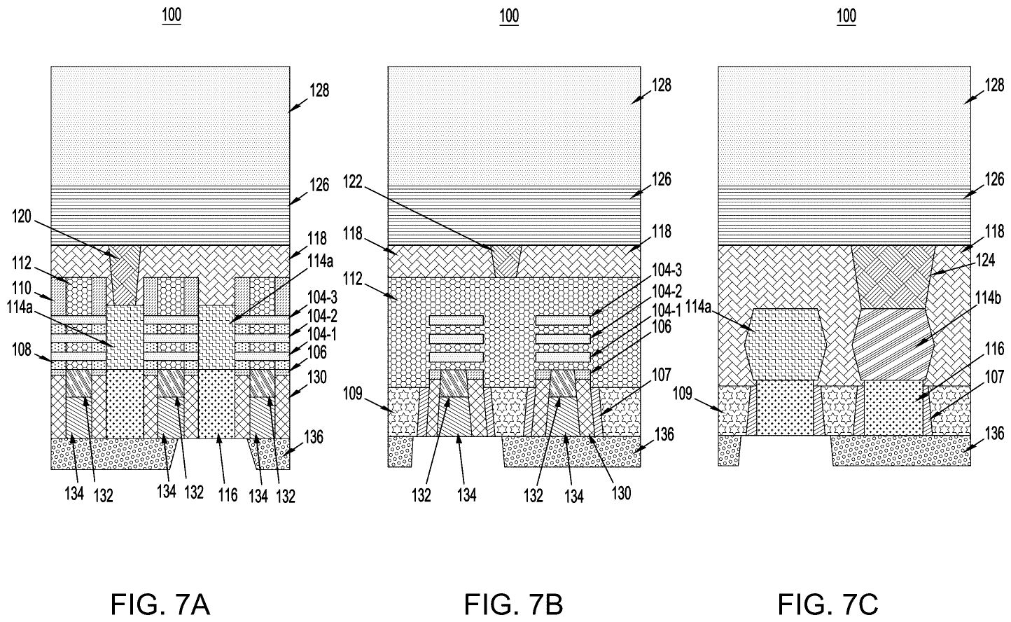

FIGS. 7A-7C illustrate semiconductor structure 100 at a seventh-intermediate fabrication stage. During this stage, a backside ILD layer 136 is deposited on semiconductor structure 100 using any convention deposition technique such as ALD, CVD, PVD, etc. Backside ILD layer 136 can be formed by similar processes and of a similar material as ILD layer 118. Next, backside ILD layer 136 is subjected to standard lithographic and patterning techniques to form backside source/drain contact openings and expose a given one of sacrificial placeholder layers 116 under source/drain regions 114a.

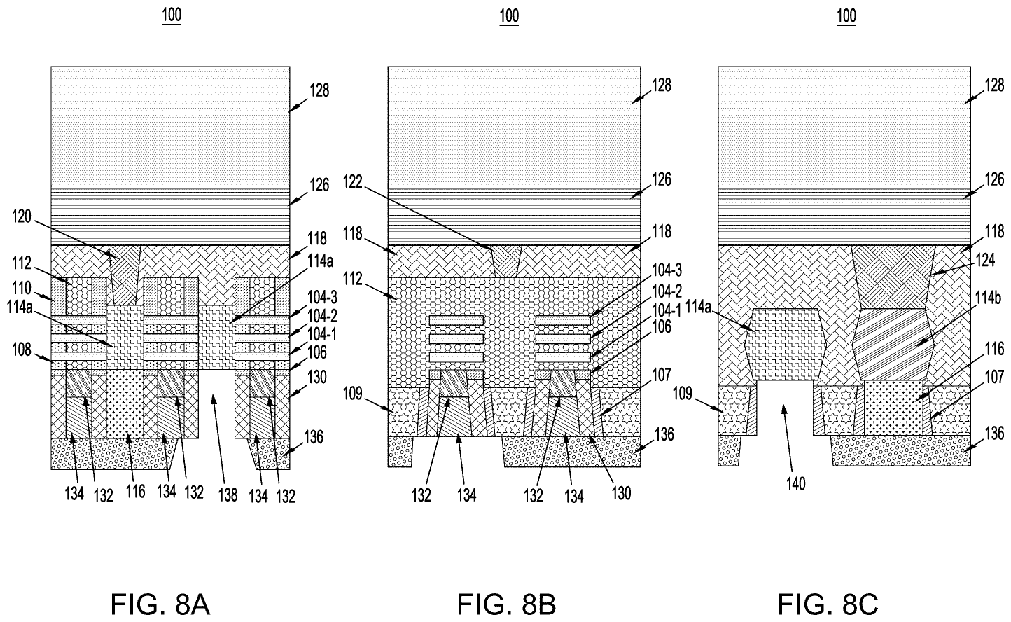

FIGS. 8A-8C illustrate semiconductor structure 100 at an eighth-intermediate fabrication stage. During this stage, the exposed sacrificial placeholder layers 116 are removed using any suitable etch processing that removes the material of sacrificial placeholder layers 116 selective to that of the rest of the structure to form backside source/drain contact openings 138 and 140. A suitable etching process includes, for example, wet etch.

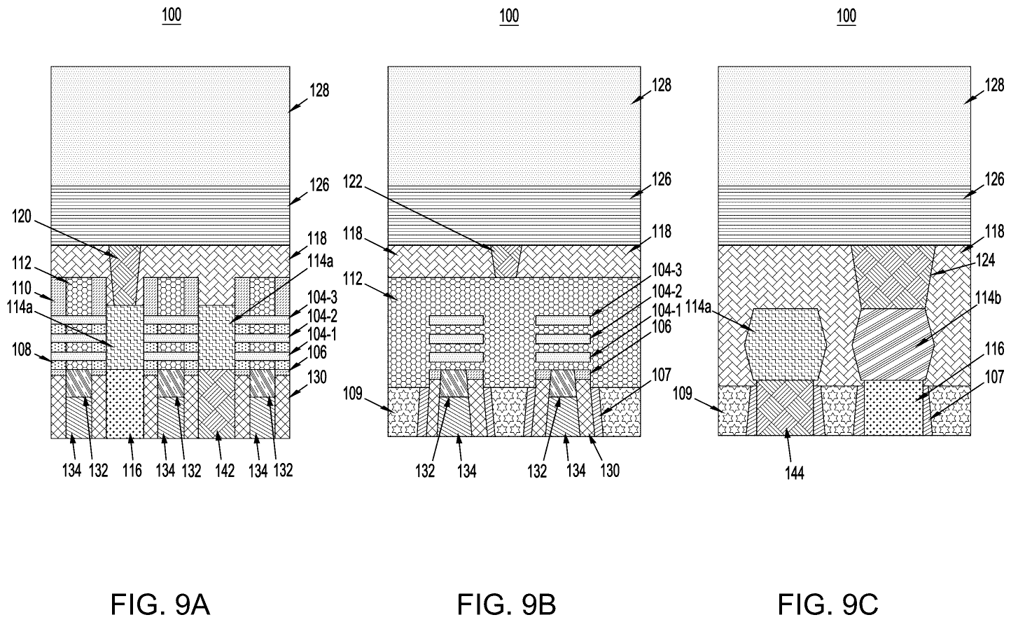

FIGS. 9A-9C illustrate semiconductor structure 100 at a ninth-intermediate fabrication stage. During this stage, backside ILD layer 136 is removed using any conventional etching process such as RIE, followed by depositing a conductive metal in backside source/drain contact openings 138 and 140 to form backside source/drain contacts 142 and 144. The backside source/drain contacts 142 and 144 can be formed by similar processes and similar material as frontside source/drain contacts 120 and 124. In various embodiments, the conductive metal can be deposited by ALD, CVD, PVD, and/or plating. The conductive metal can be planarized using, for example, a planarizing process such as CMP. Other planarization processes can include grinding and polishing.

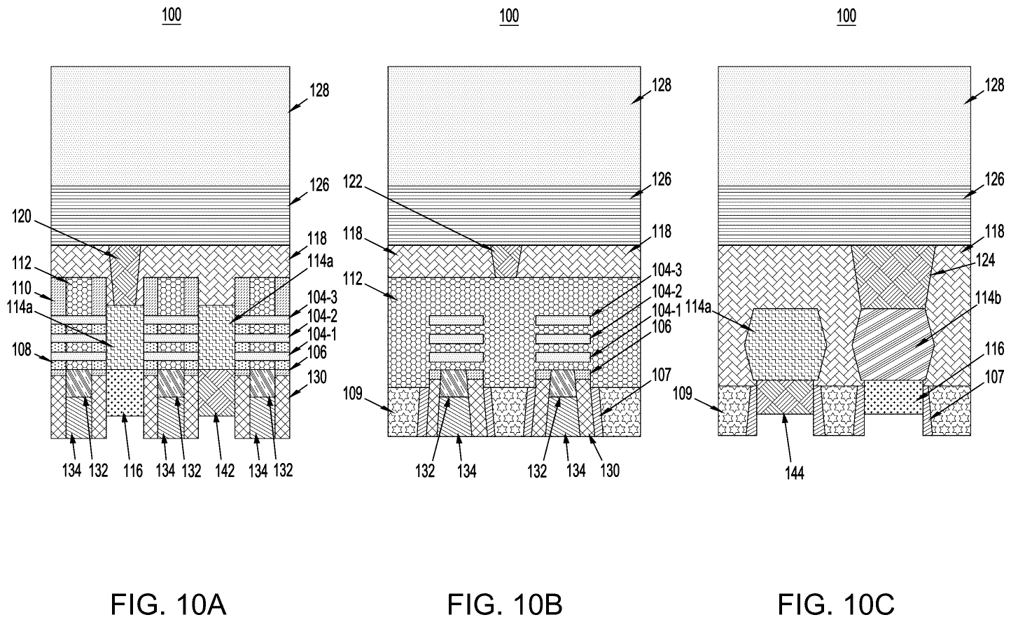

FIGS. 10A-10C illustrate semiconductor structure 100 at a tenth-intermediate fabrication stage. During this stage, the remaining sacrificial placeholder layers 116 and backside source/drain contacts 142 and 144 are selectively recessed using any conventional etching process such as RIE to expose a portion of liner layer 107 and conformal spacer layer 130.

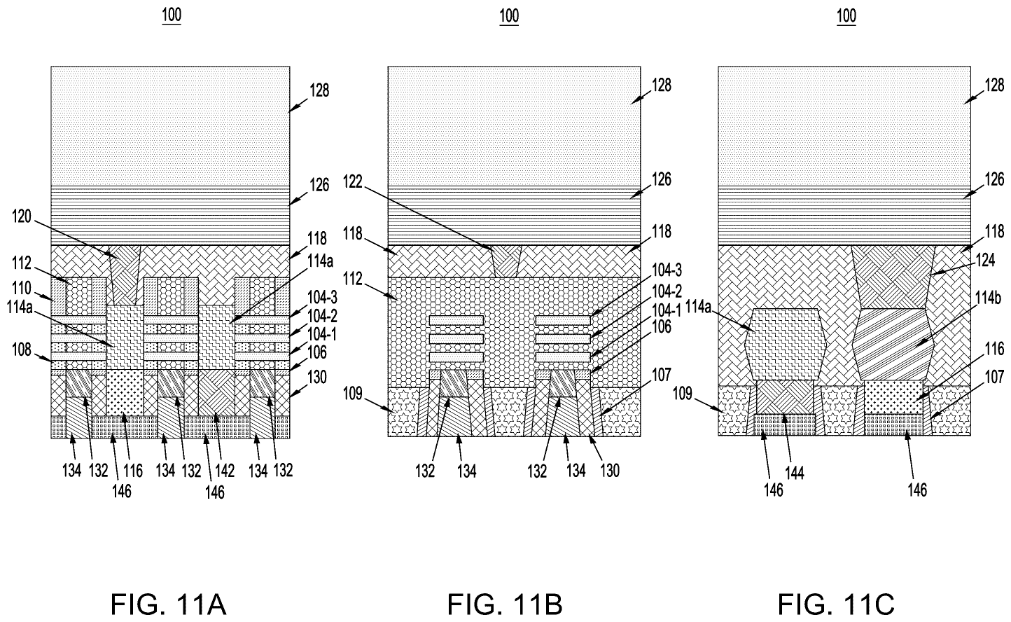

FIGS. 11A-11C illustrate semiconductor structure 100 at an eleventh-intermediate fabrication stage. During this stage, the exposed conformal spacer layer 130 is selectively removed using any conventional selective etching process such as a wet or dry etch. Next, a backside source/drain contact cap layer 146 is deposited on the exposed surfaces of liner layer 107, sacrificial placeholder layers 116, conformal spacer layer 130 and backside source/drain contacts 142 and 144 using any conventional deposition technique such as ALD, CVD, PVD, etc. Suitable material for backside source/drain contact cap layer 146 includes, for example, a nitride containing material such as SiN, SiBCN, SiOCN, etc. A planarization process such as CMP can be carried if necessary.

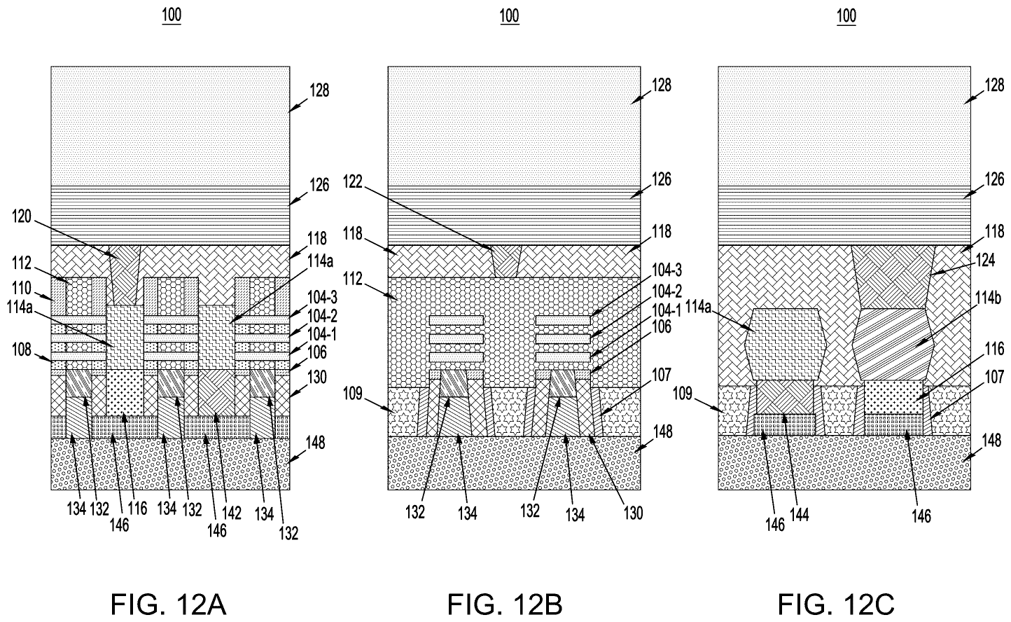

FIGS. 12A-12C illustrate semiconductor structure 100 at a twelfth-intermediate fabrication stage. During this stage, an additional backside ILD layer 148 is deposited on semiconductor structure 100 using any conventional deposition technique such as ALD, CVD, PVD, etc. Additional backside ILD layer 148 can be formed by similar processes and of a similar material as ILD layer 118.

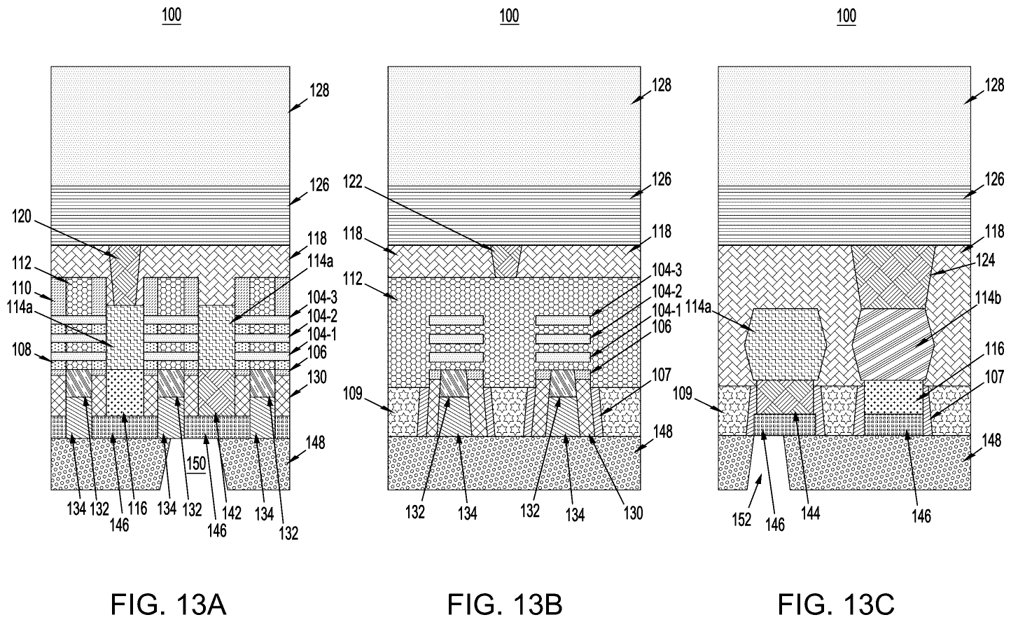

FIGS. 13A-13C illustrate semiconductor structure 100 at a thirteenth-intermediate fabrication stage. During this stage, additional backside ILD layer 148 is subjected to conventional lithographic and etching processes such as RIE to form backside source/drain contact vias 150 and 152 in the exposed additional backside ILD layer 148. FIG. 13A shows backside source/drain contact via 150 being formed exposing a portion of conformal spacer layer 130, backside gate extension cap layer 134 and backside source/drain contact cap layer 146 under backside source/drain contact 142. FIG. 13C shows backside source/drain contact via 152 being formed exposing a portion of backside source/drain contact cap layer 146 under backside source/drain contact 144.

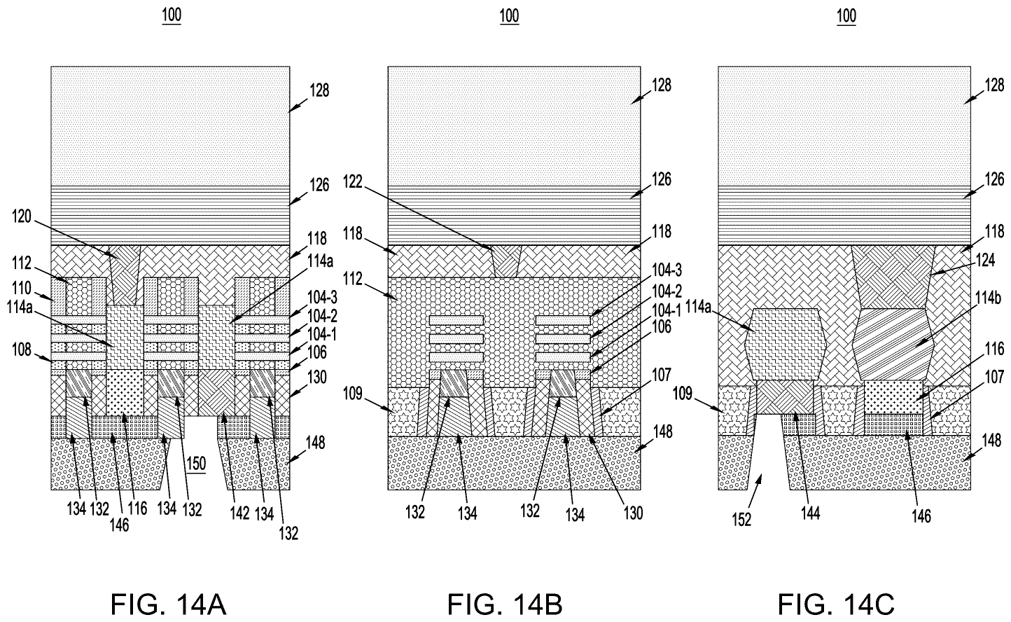

FIGS. 14A-14C illustrate semiconductor structure 100 at a fourteenth-intermediate fabrication stage. During this stage, the exposed backside source/drain contact cap layer 146 is selectively removed in backside source/drain contact via 150 (FIG. 14A) using a selective etching process that is selective to the exposed backside source/drain contact cap layer 146 relative to conformal spacer layer 130 and backside source/drain contact 142. A suitable etching process is a wet or dry etch.

Next, the exposed backside source/drain contact cap layer 146 is selectively removed in backside source/drain contact via 152 (FIG. 14C) using a selective etching process that is selective to the exposed backside source/drain contact cap layer 146 relative to liner layer 107 and backside source/drain contact 142. A suitable etching process is a wet or dry etch.

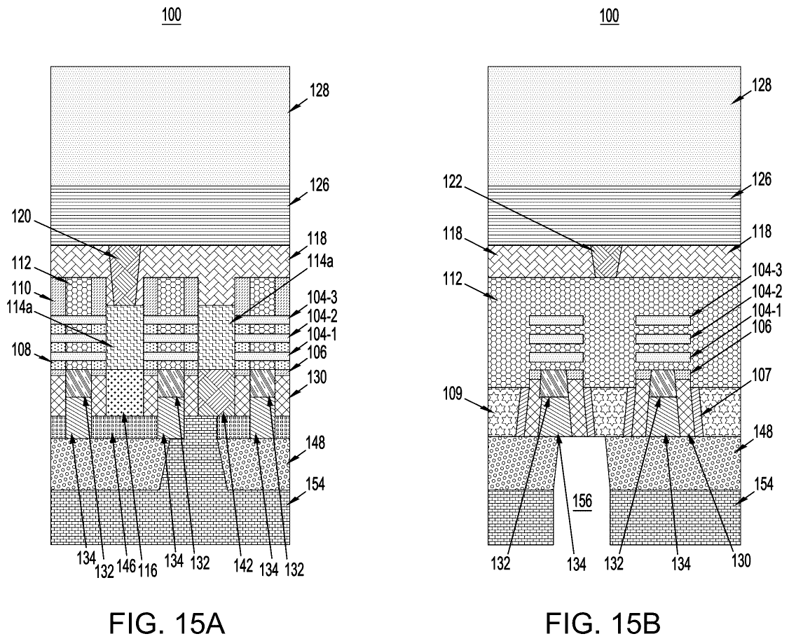

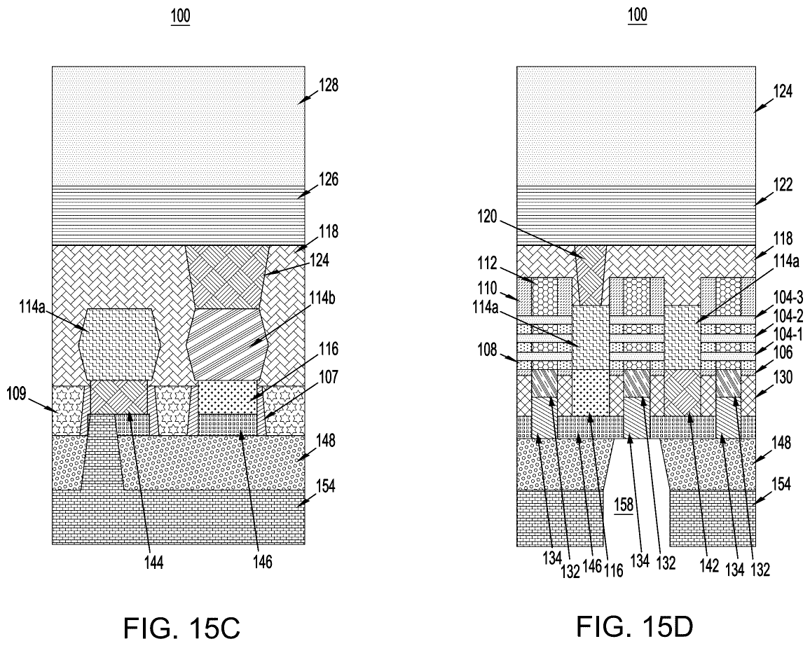

FIGS. 15A-15D illustrate semiconductor structure 100 at a fifteenth-intermediate fabrication stage. During this stage, a mask layer 154 (such as an organic planarization layer (OPL) or a spin-on-carbon (SOC)) is deposited in backside source/drain contact vias 150 and 152 and on additional backside ILD layer 148. For example, in an illustrative embodiment, mask layer 154 is deposited in backside source/drain contact vias 150 and 152 and on additional backside ILD layer 148 using spin-on coating or any other suitable deposition process.

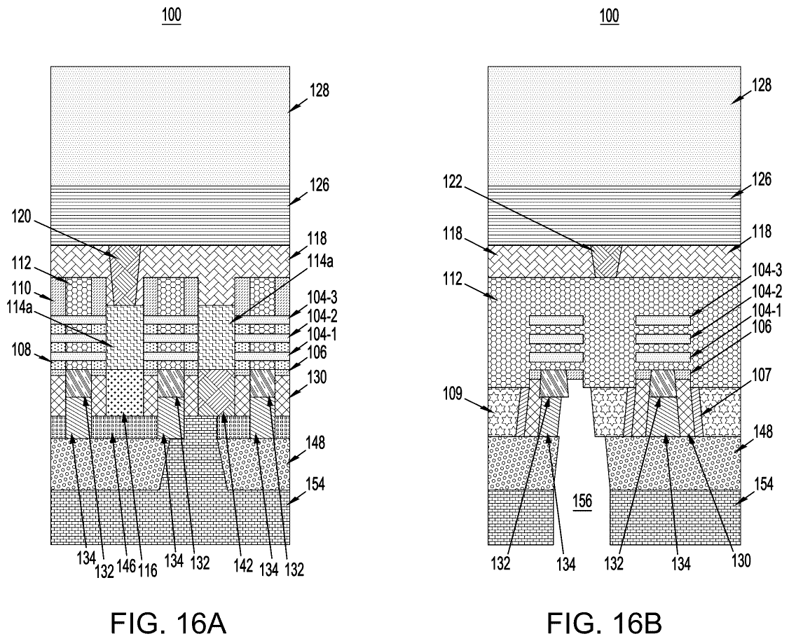

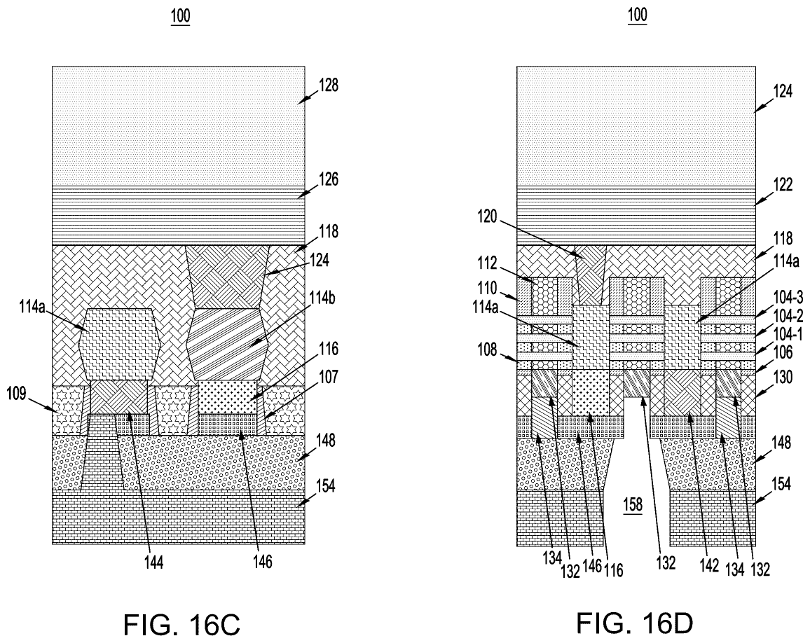

FIGS. 16A-16D illustrate semiconductor structure 100 at a sixteenth-intermediate fabrication stage. During this stage, mask layer 154 is patterned and a selective etch process such as RIE can be carried out to selectively remove the exposed portions of mask layer 154, additional backside ILD layer 148, backside gate extension cap layer 134 and conformal spacer layer 130 leaving backside gate contact via 156. FIG. 16B shows a backside gate contact via 156 being formed exposing backside gate extension cap layer 134, backside gate extension 132, STI regions 109 and SASI layer 106.

Mask layer 154 is further patterned and a selective etch process such as RIE can be carried out to selectively remove the exposed portions of mask layer 154, additional backside ILD layer 148, backside source/drain contact cap layer 146 and backside gate extension cap layer 134 leaving a backside gate contact via 158. FIG. 16D shows backside gate contact via 158 exposing backside source/drain contact cap layer 146, backside gate extension 132 and conformal spacer layer 130.

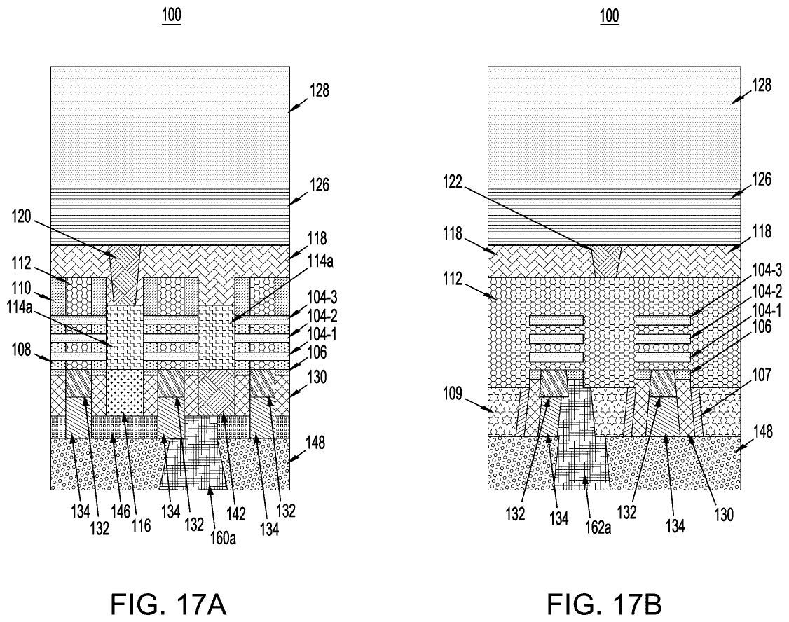

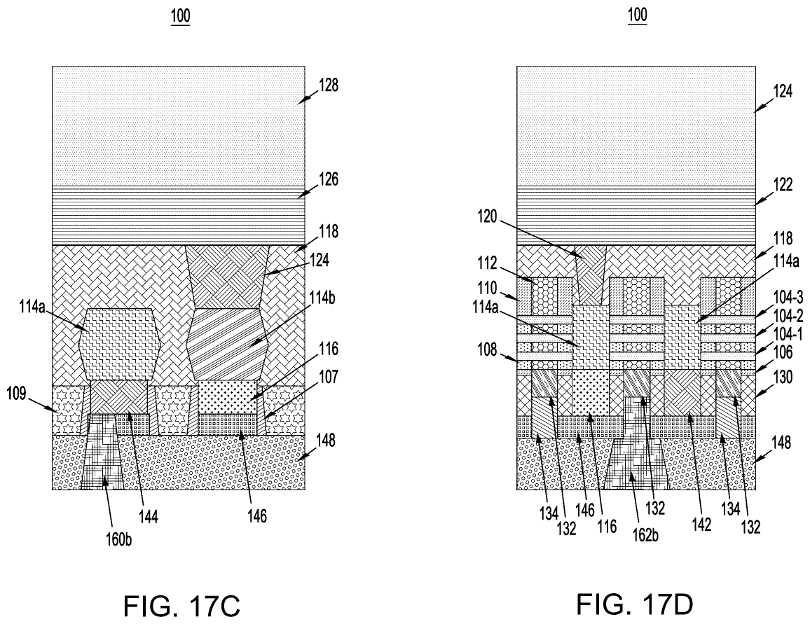

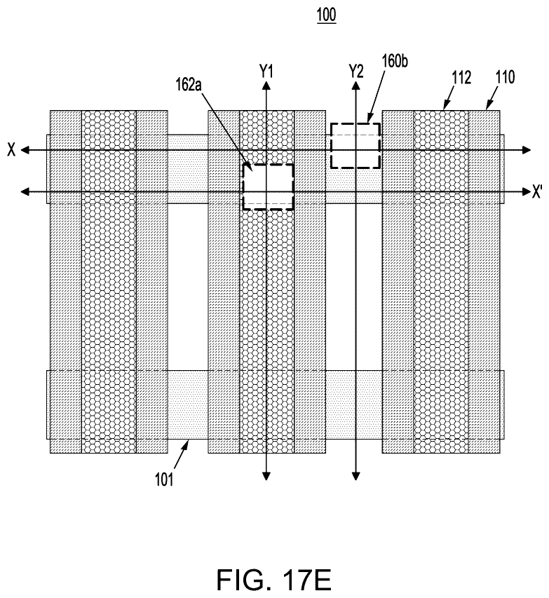

FIGS. 17A-17E illustrate semiconductor structure 100 at a seventeenth-intermediate fabrication stage. During this stage, backside source/drain contacts 160a and 160b and backside gate contacts 162a and 162b are formed. For example, in illustrative embodiments, mask layer 154 is first removed by, for example, an ash etching process, followed by deposition of a suitable conductive metal in each of the openings. The conductive metal can be deposited in a similar manner and of a similar material as discussed above. Any overfill of the conductive metal can be removed by a planarization process such as CMP.

FIG. 17A shows backside source/drain contact 160a being partially disposed on backside gate extension cap layer 134 and backside source/drain contact 142.

FIG. 17B shows backside gate contact 162a being partially disposed on backside gate extension 132. Thus, backside gate contact 162a can also be referred to as partially wrapped-around backside contact.

FIG. 17C shows backside source/drain contact 160b being disposed on backside source/drain contact 144 and backside source/drain contact cap layer 146.

FIG. 17D shows backside gate contact 162b being disposed on backside gate extension 132 and backside source/drain contact cap layer 146.

FIG. 17E shows that backside source/drain contact 160b and backside gate contact 162a are not aligned with each other.

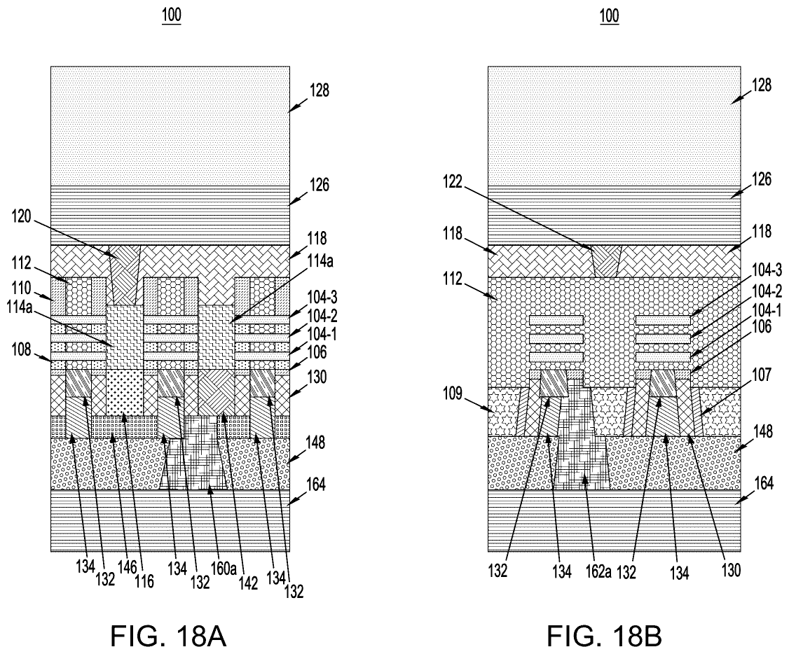

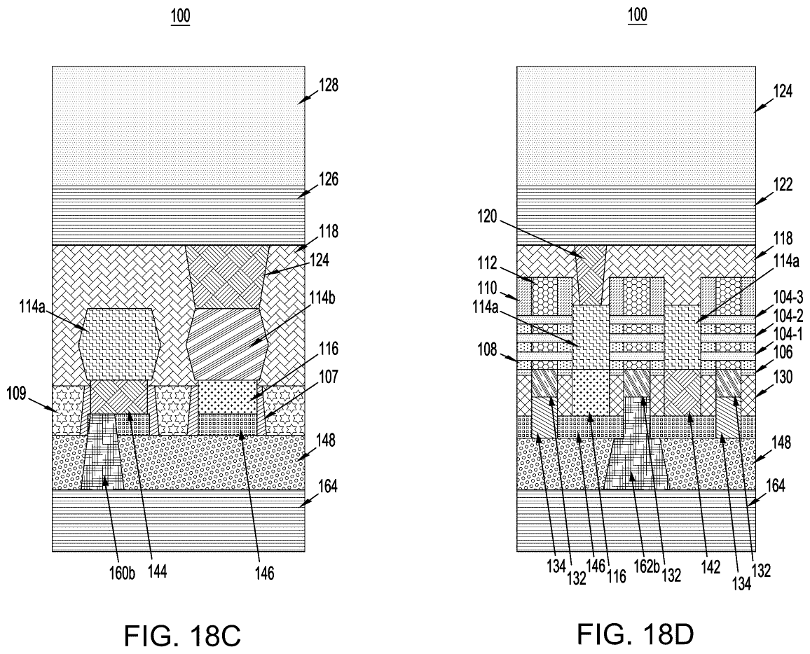

FIGS. 18A-18D illustrate semiconductor structure 100 at an eighteenth-intermediate fabrication stage. During this stage, a backside interconnect 164 is formed over the structure. The power signals can be routed through backside interconnect 164 containing metal lines coupled to the semiconductor structure to provide power to a number of semiconductor devices. Backside interconnect 164 is formed over the structure including backside power lines and is based on creation of a wiring scheme that is disposed on both sides of the device layer (front end of line structure). In some embodiments, the backside interconnect is a backside interconnect wiring structure providing a backside power delivery network.

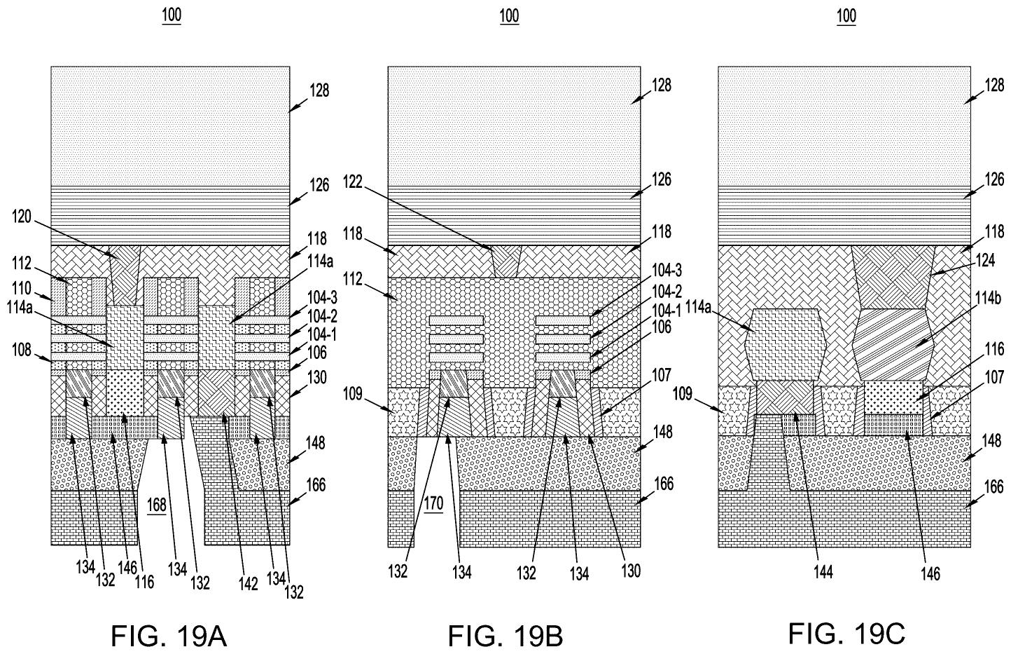

FIGS. 19A-22C illustrate an alternative embodiment for forming semiconductor structure 100 having a backside cross-couple connect starting from FIG. 12A. FIG. 19A-19C show semiconductor structure 100 having backside gate contact vias 168 and 170 according to an illustrative embodiment. For example, backside gate contact vias 168 and 170 can be formed by first subjecting additional backside ILD layer 148 to standard lithographic and etching processes to form a backside source/drain contact via and backside gate contact via, followed be selectively removing a portion of backside source/drain contact cap layer 146 under backside source/drain contact 142 using a selective etching process such as RIE. Next, a mask layer 166 is deposited in the backside source/drain contact via and backside gate contact via and on additional backside ILD layer 148. Mask layer 166 can be formed by similar processes and of similar material as mask layer 154. Mask layer 166 is patterned and a selective etch process such as RIE can be carried out to selectively remove the exposed portions of mask layer 166 leaving backside gate contact vias 168 and 170.

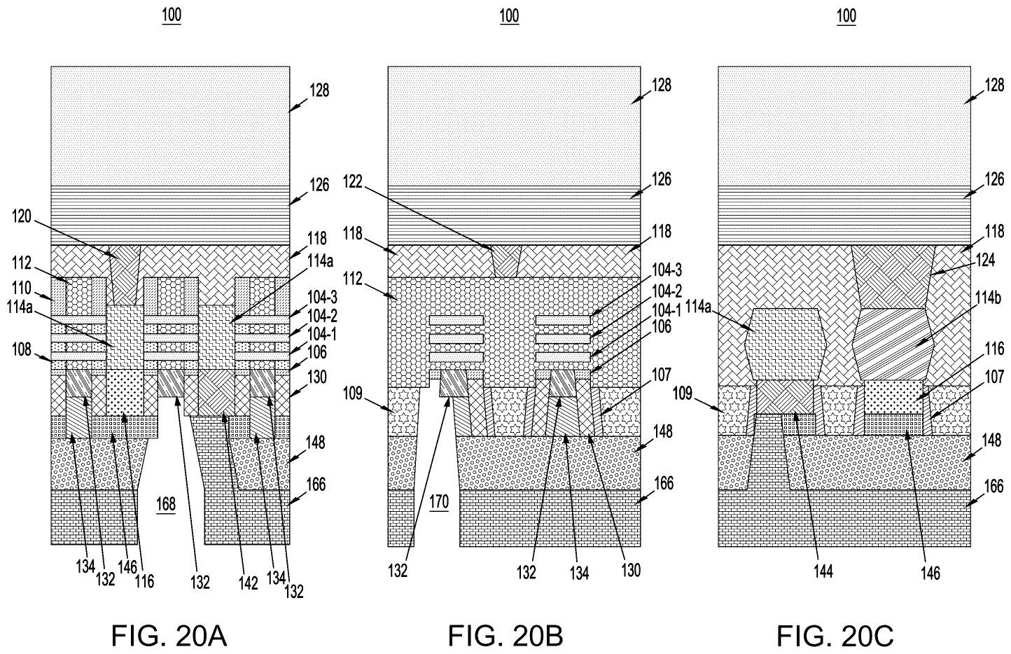

FIGS. 20A-20C illustrate semiconductor structure 100 at a second-intermediate fabrication stage. During this stage, backside gate extension cap layer 134, conformal spacer layer 130 and liner layer 107 are selectively removed from backside gate contact vias 168 and 170 using a selective etch process such as a wet or dry etch. FIG. 20A shows backside gate contact via 168 exposing backside gate extension 132, backside source/drain contact cap layer 146, and conformal spacer layer 130. FIG. 20B shows backside gate contact via 170 exposing backside gate extension 132, backside gate extension cap layer 134, conformal spacer layer 130 and STI regions 109.

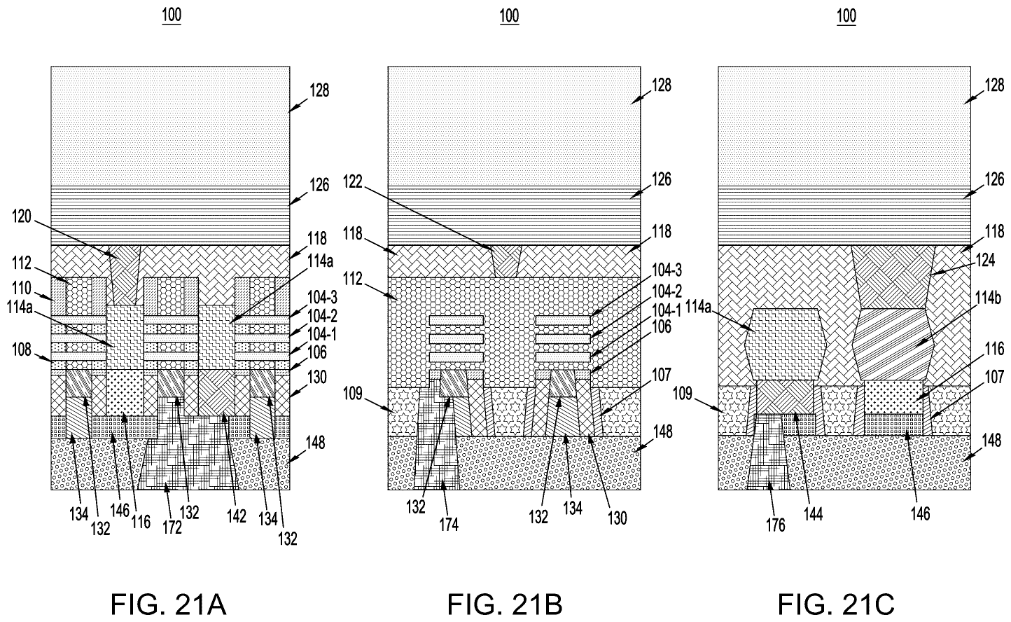

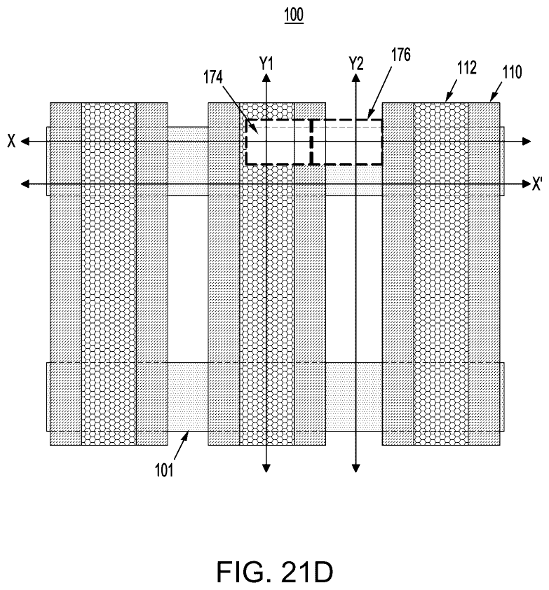

FIGS. 21A-21D illustrate semiconductor structure 100 at a third-intermediate fabrication stage. During this stage, a backside contact 172, a backside gate contact 174 and a backside source/drain contact 176 are formed. For example, in illustrative embodiments, mask layer 166 is first removed by, for example, an ash etching process, followed by deposition of a suitable conductive metal in each of the openings. The conductive metal can be deposited in a similar manner and of a similar material as discussed above. Any overfill of the conductive metal can be removed by a planarization process such as CMP.

FIG. 21A shows backside contact 172 being partially disposed on backside gate extension 132 and backside source/drain contact 142 and participates as a backside cross-couple connect.

FIG. 21B shows backside gate contact 174 being partially disposed on backside gate extension 132. Thus, backside gate contact 174 can also be referred to as partially wrapped-around backside gate extension 132.

FIG. 21C shows backside source/drain contact 176 disposed on backside source/drain contact 144.

FIG. 21D shows backside gate contact 174 aligned with backside source/drain contact 176. In some embodiments, backside gate contact 174 and backside source/drain contact 176 are a backside cross-couple connect connecting backside gate extension 132 to backside source/drain contact 144.

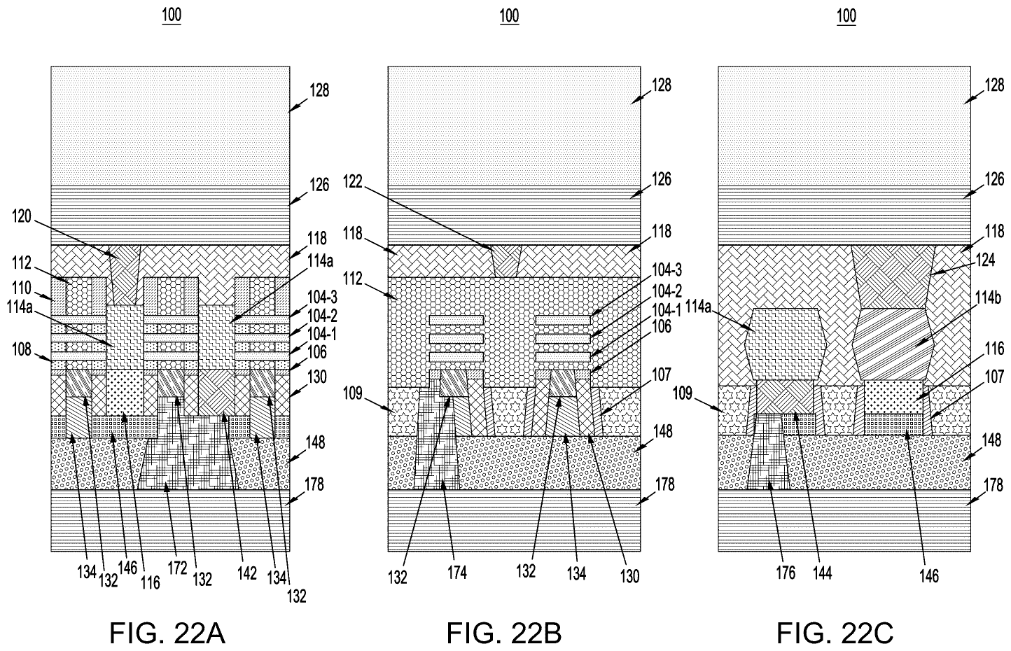

FIGS. 22A-22C illustrate semiconductor structure 100 at a fourth-intermediate fabrication stage. During this stage, a backside interconnect 178 is formed over the structure. The power signals can be routed through backside interconnect 178 containing metal lines coupled to the semiconductor structure to provide power to a number of semiconductor devices. Backside interconnect 178 is formed over the structure including backside power lines and is based on creation of a wiring scheme that is disposed on both sides of the device layer (front end of line structure).

According to an aspect of the invention, a semiconductor structure comprises a backside gate extension extending from a frontside gate region through a dielectric isolation layer, a backside gate contact partially disposed on the backside gate extension, and a backside interconnect connected to the backside gate extension by the backside gate contact.

In embodiments, the semiconductor structure further comprises a backside gate extension cap layer disposed on the backside gate extension.

In embodiments, the backside gate contact is further partially disposed on the backside gate extension cap layer.

In embodiments, the semiconductor structure further comprises a first frontside source/drain region and a second frontside source/drain region, a backside source/drain contact disposed on the first frontside source/drain region, and a first backside source/drain contact cap layer disposed on the backside source/drain contact.

In embodiments, the semiconductor structure further comprises a backside sacrificial placeholder disposed on the second frontside source/drain region, and a second backside source/drain contact cap layer disposed on the backside sacrificial placeholder.

In embodiments, the semiconductor structure further comprises a backside source/drain contact via connecting a backside source/drain contact to the backside interconnect.

In embodiments, the semiconductor structure further comprises a backside source/drain contact cap layer disposed on the backside source/drain contact and the backside source/drain contact via:

In embodiments, the frontside gate region is disposed within a nanosheet field-effect transistor.

In embodiments, the semiconductor structure further comprises a frontside metal gate contact connecting the frontside gate region to a frontside back-end-of-the line interconnect.

According to an aspect of the invention, a semiconductor structure comprises a backside gate extension extending from a frontside gate region through a dielectric isolation layer, and a backside cross-couple connect connecting a backside source/drain contact to the backside gate extension.

The semiconductor structure of the illustrative embodiment advantageously allows for a backside interconnect to have a power line and a signal line thereby reducing process complexity and improving routing congestion.

In embodiments, the backside cross-couple connect is partially disposed on the backside gate extension.

In embodiments, the semiconductor structure further comprises a backside gate extension cap layer disposed on the backside gate extension.

In embodiments, the backside cross-couple connect is further partially disposed on the backside gate extension cap layer.

In embodiments, the semiconductor structure further comprises a first frontside source/drain region disposed on the backside source/drain contact, and a backside source/drain contact cap layer disposed on the backside source/drain contact and the backside cross-couple connect.

In embodiments, the semiconductor structure further comprises a second frontside source/drain region adjacent the first frontside source/drain region, and a source/drain metal contact connecting the second frontside source/drain region to a back-end-of-the line interconnect.

In embodiments, the frontside gate region is disposed within a nanosheet field-effect transistor.

In embodiments, the semiconductor structure further comprises a frontside metal gate contact connecting the frontside gate region to a frontside back-end-of-the line interconnect.

According to an aspect of the invention, an integrated circuit comprises one or more semiconductor structures, wherein at least one of the one or more semiconductor structures comprises a backside gate extension extending from a frontside gate region through a dielectric isolation layer, a backside gate contact partially disposed on the backside gate extension, and a backside interconnect connected to the backside gate extension by the backside gate contact.

In embodiments, the at least one of the one or more semiconductor structures further comprises a backside gate extension cap layer disposed on the backside gate extension.

In embodiments, the backside gate contact is further partially disposed on the backside gate extension cap layer.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a backside gate extension extending from a frontside gate region through a dielectric isolation layer;
a backside gate contact partially disposed on the backside gate extension; and
a backside interconnect connected to the backside gate extension by the backside gate contact.

2. The semiconductor structure according to claim 1, further comprising a backside gate extension cap layer disposed on the backside gate extension.

3. The semiconductor structure according to claim 2, wherein the backside gate contact is further partially disposed on the backside gate extension cap layer.

4. The semiconductor structure according to claim 1, further comprising:
a first frontside source/drain region and a second frontside source/drain region;
a backside source/drain contact disposed on the first frontside source/drain region; and
a first backside source/drain contact cap layer disposed on the backside source/drain contact.

5. The semiconductor structure according to claim 4, further comprising:
a backside sacrificial placeholder disposed on the second frontside source/drain region; and
a second backside source/drain contact cap layer disposed on the backside sacrificial placeholder.

6. The semiconductor structure according to claim 1, further comprising:
a backside source/drain contact via connecting a backside source/drain contact to the backside interconnect.

7. The semiconductor structure according to claim 6, further comprising:
a backside source/drain contact cap layer disposed on the backside source/drain contact and the backside source/drain contact via.

8. The semiconductor structure according to claim 1, wherein the frontside gate region is disposed within a nanosheet field-effect transistor.

9. The semiconductor structure according to claim 8, further comprising:
a frontside metal gate contact connecting the frontside gate region to a frontside back-end-of-the line interconnect.

10. A semiconductor structure, comprising:
a backside gate extension extending from a frontside gate region through a dielectric isolation layer; and
a backside cross-couple connect connecting a backside source/drain contact to the backside gate extension.

11. The semiconductor structure according to claim 10, wherein the backside cross-couple connect is partially disposed on the backside gate extension.

12. The semiconductor structure according to claim 11, further comprising:
a backside gate extension cap layer disposed on the backside gate extension.

13. The semiconductor structure according to claim 12, wherein the backside cross-couple connect is further partially disposed on the backside gate extension cap layer.

14. The semiconductor structure according to claim 10, further comprising:
a first frontside source/drain region disposed on the backside source/drain contact; and
a backside source/drain contact cap layer disposed on the backside source/drain contact and the backside cross-couple connect.

15. The semiconductor structure according to claim 14, further comprising:
a second frontside source/drain region adjacent the first frontside source/drain region; and
a source/drain metal contact connecting the second frontside source/drain region to a back-end-of-the line interconnect.

16. The semiconductor structure according to claim 10, wherein the frontside gate region is disposed within a nanosheet field-effect transistor.

17. The semiconductor structure according to claim 16, further comprising:
a frontside metal gate contact connecting the frontside gate region to a frontside back-end-of-the line interconnect.

18. An integrated circuit, comprising:
one or more semiconductor structures, wherein at least one of the one or more semiconductor structures comprises:
a backside gate extension extending from a frontside gate region through a dielectric isolation layer;
a backside gate contact partially disposed on the backside gate extension; and
a backside interconnect connected to the backside gate extension by the backside gate contact.

19. The integrated circuit according to claim 18, further comprising:
a backside gate extension cap layer disposed on the backside gate extension.

20. The integrated circuit according to claim 19, wherein the backside gate contact is further partially disposed on the backside gate extension cap layer.
